(19) United States
(12) Patent Application Publication
(10) Pub. No.: US 2008/0017897 A1
(43) Pub. Date: Jan. 24, 2008

(54) SEMICONDUCTOR DEVICE AND METHOD OF MANUFACTURING SAME

(75) Inventors: Wataru SAITO, Kanagawa-ken (JP); Syotaro Ono, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/668,861

(22) Filed: Jan. 30, 2007

(30) Foreign Application Priority Data
Jan. 30, 2006 (JP) 2006-021488
May 2, 2006 (JP) 2006-128698

(51) Int. Cl. H01L 21/8238; H01L 29/76

(52) U.S. Cl. 257/288; 438/212; 257/E29.226; 257/E21.632

(57) ABSTRACT

A semiconductor device includes: a semiconductor layer of a first conductivity type; a plurality of first semiconductor pillar regions of the first conductivity type provided on a major surface of the semiconductor layer; a plurality of second semiconductor pillar regions of a second conductivity type being adjacent to the first semiconductor pillar regions; a first main electrode provided on a side opposite to the major surface of the semiconductor layer; a first semiconductor region of the second conductivity type provided on the second semiconductor pillar regions; a second semiconductor region of the first conductivity type provided in a surface portion of the first semiconductor region; a second main electrode provided on the second semiconductor region; a trench being adjacent to the first semiconductor region and the second semiconductor region and reaching the first semiconductor pillar region from the surface side of the second semiconductor region; an insulating film provided on an inner wall surface of the trench; and a control electrode buried inside the trench via the insulating film. The doping concentration in the vertical direction at the center of the width of the second semiconductor pillar region is substantially constant up to a substantially intermediate portion in the direction from the second main electrode toward the first main electrode and gradually decreases from the substantially intermediate portion toward the first main electrode.

### CROSS-REFERENCE TO RELATED APPLICATIONS

This application is based upon and claims the benefit of priorities from the prior Japanese Patent Application No. 2006-21488, filed on Jan. 30, 2006, and the prior Japanese Patent Application No. 2006-128698, filed on May 2, 2006; the entire contents of which are incorporated herein by reference.

### BACKGROUND OF THE INVENTION

1. Field of the Invention

This invention relates to a semiconductor device having a so-called superjunction structure and a method of manufacturing the same.

2. Background Art

MOSFETs (Metal Oxide Semiconductor Field Effect Transistors) suitable for power electronics application have been conventionally known. The ON resistance of this power MOSFET greatly depends on the electric resistance of the conduction layer (drift layer). The electric resistance of the drift layer is determined by the doping concentration in the drift layer, and the ON resistance can be decreased by increasing the doping concentration. However, as the doping concentration in the drift layer increases, the width of the depletion layer spreading from the pn junction between the drift layer and the base region is narrowed. Then the maximum electric field intensity of silicon is reached at a lower voltage, and the device breakdown voltage is decreased. Hence the doping concentration in the drift layer cannot exceed the limit that depends on the breakdown voltage. Thus, there is a tradeoff between the device breakdown voltage and the ON resistance. This tradeoff applies similarly to IGBTs (Insulated Gate Bipolar Transistors), diodes, and bipolar transistors This problem is also in common with lateral semiconductor elements where the direction of the drift current during ON state is different from the extending direction of the depletion layer under reverse bias during OFF state. Improving this tradeoff is important for offering power semiconductor devices with low power consumption. The tradeoff between the device breakdown voltage and the ON resistance has a limit determined by the material of the device. Overcoming this limit is the way to realizing power semiconductor devices with low ON resistance.

An example MOSFET to solve this problem is a structure known as a “superjunction structure” in the drift layer, where p-type pillar regions and n-type pillar regions shaped as a vertically elongated strip are juxtaposed alternately in the horizontal direction relative to the current path (JP 2003-115589A). In the superjunction structure, a non-doped layer is artificially produced by equalizing the amount of dopant contained in the p-type pillar region and the n-type pillar region. While maintaining high breakdown voltage, a drift current is allowed to flow through the highly doped n-type pillar region during ON state, thereby realizing low ON resistance exceeding the material limit.

A tradeoff exceeding the material limit can be achieved between the ON resistance and the breakdown voltage by using the superjunction structure. However, the lateral period of the superjunction structure needs to be narrowed for increasing the amount of dopant in the p-type and n-type pillar region to reduce the ON resistance. If the amount of dopant in the p-type and n-type pillar region is increased without narrowing the lateral period, the lateral electric field for completely depleting the superjunction structure is increased, and the vertical electric field determining the breakdown voltage is decreased. Thus the breakdown voltage is decreased together with the ON resistance. Therefore it is indispensable to narrow the lateral period of the superjunction structure for reducing the ON resistance while maintaining high breakdown voltage.

When the lateral period of the superjunction structure is narrowed, the lateral period of the MOS gate structure (MOS cell pitch) formed in the surface must also be narrowed. This is because, without similar downscaling of the MOS gate structure, the resistance is increased in the MOS gate structure, showing no promise to reduce the overall ON resistance of the device.

Reduction of the source contact width is effective for reducing the MOS cell pitch. However, reduction of the source contact width results in increasing the aspect ratio of the source contact hole (insulating film thickness of the source contact portion/source contact width). When this aspect ratio is increased, the performance of burying source metal into the contact hole is deteriorated, and the source electrode resistance is increased.

On the other hand, Japanese Patent No. 3634830 discloses a superjunction structure where the decrease of breakdown voltage due to the difference of the amount of dopant (amount of imbalance) between the p-type pillar region and the n-type pillar region is reduced to expand the process margin. To this end, as compared with the doping concentration in the n-type pillar region, the doping concentration in the p-type pillar region is made higher in the upper portion (on the source electrode side) and lower in the lower portion (on the drain electrode side) with a slope of concentration gradually decreasing from the source electrode toward the drain electrode.

To improve the tradeoff between the ON resistance and the breakdown voltage of a power MOSFET having a superjunction structure, in the case of an n-channel device, it is required that the doping concentration in the n-type pillar region serving as a current path be increased to reduce the ON resistance while downscaling the p/n-pillar region so as to be depleted even at high concentration during OFF state. That is, a technique for forming a p/n-pillar region having a higher aspect ratio than conventional one is required. In addition, in the structure where the width of the n-type pillar region is narrowed to 5 μm or less, it is required to reduce the cell pitch of the MOS section. Currently, in typical DMOS (double diffused MOS) planar gate structures, it is difficult to reduce the cell pitch to 10 μm or less. Hence, as the structure of the MOS section, use of a trench gate structure having more possibility of downscaling is contemplated so that the channel density can follow the downscaled p/n-pillar region (see, e.g., JP 2005-101560A). In the current technology, it is possible to reduce the width of a trench gate to 0.5 μm or less. Thus, even if the n-type pillar region has a width of 5 μm (i.e., assuming that half the 10-μm cell pitch corresponds to the n-type pillar region), each n-type pillar region can well afford to place a trench gate therein. Therefore the channel density can well follow the downscaling of the p/n-pillar region.

In a configuration where a trench gate structure is used in the MOS section with the p/n-pillar region being downscaled, the process margin may be expanded as disclosed in Japanese Patent No. 3634830. Specifically, the doping concentration in the p-type pillar region may be sloped. That is, in the upper portion of the pillar region (on the source electrode side), the doping concentration in the p-type pillar region is made higher (p-pillar rich) than in the n-type pillar region. However, partly because of the downscaled n-type pillar region, the depletion layer tends to extend to the n-type pillar region, hence increasing the spreading resistance to electrons supplied from the channel to the n-type pillar region. Furthermore, during OFF state, the depletion layer from the trench gate also extends to the n-type pillar region. Therefore, even if all the p/n-pillar regions are provided with a uniform doping concentration, the depletion layer tends to extend to the n-type pillar region in the upper portion of the pillar region. This is likely to prevent the downscaling of the pillar region.

### SUMMARY OF THE INVENTION

According to an aspect of the invention, there is provided a semiconductor device including: a semiconductor layer of a first conductivity type; a plurality of first semiconductor pillar regions of the first conductivity type provided on a major surface of the semiconductor layer; a plurality of second semiconductor pillar regions of a second conductivity type provided on the major surface of the semiconductor layer and being adjacent to the first semiconductor pillar regions; a first main electrode provided on a side opposite to the major surface of the semiconductor layer; a first semiconductor region of the second conductivity type provided on the first and second semiconductor pillar regions; a second semiconductor region of the first conductivity type provided in a surface portion of the first semiconductor region; a second main electrode provided on the second semiconductor region; a trench being adjacent to the first semiconductor region and the second semiconductor region and reaching the first semiconductor pillar region from the surface side of the second semiconductor region; an insulating film provided on an inner wall surface of the trench; and a control electrode buried inside the trench via the insulating film, doping concentration in the vertical direction at the center of the width of the second semiconductor pillar region being substantially constant up to a substantially intermediate portion in the direction from the second main electrode toward the first main electrode and gradually decreasing from the substantially intermediate portion toward the first main electrode.

According to another aspect of the invention, there is provided a semiconductor device including: a semiconductor layer of a first conductivity type; a first semiconductor pillar region of the first conductivity type provided on a major surface of the semiconductor layer; a second semiconductor pillar region of a second conductivity type provided on the major surface of the semiconductor layer and being adjacent to the first semiconductor pillar region; a first main electrode provided on an opposite side of the major surface of the semiconductor layer; a first semiconductor region of the second conductivity type provided on the second semiconductor pillar region; a second semiconductor region of the first conductivity type selectively provided in a surface of the first semiconductor region; a second main electrode provided on the first semiconductor region and the second semiconductor region; a first insulating film provided on the first semiconductor pillar region, the first semiconductor region, and the second semiconductor region; a control electrode provided on the first insulating film; a second insulating film provided on the control electrode; and a third insulating film provided on the major surface side of the semiconductor layer in a terminal section adjacent to a device section where the control electrode is located, a thickness of the second insulating film is ⅓ or less of a thickness of the third insulating film.

According to another aspect of the invention, there is provided a method of manufacturing a semiconductor device including: etching a first semiconductor layer of a first conductivity type from a major surface side thereof in a plurality of steps to form a trench having a width that is narrowed stepwise along the depth from the major surface side; burying a second semiconductor layer of a second conductivity type in the trench; forming a first semiconductor region of the second conductivity type in a surface portion of the second semiconductor layer; forming a second semiconductor region of the first conductivity type in a surface portion of the first semiconductor region; forming a first main electrode on an opposite side of the major surface of the first semiconductor layer; and forming a second main electrode in contact with the second semiconductor region.

### BRIEF DESCRIPTION OF THE DRAWINGS

FIG. 1A is a schematic view illustrating the cross-sectional structure of the main part of a semiconductor device according to a first embodiment of the invention, and FIG. 1B is a schematic diagram showing the variation of doping concentration along the depth in the semiconductor device.

FIG. 2 is a schematic view illustrating the planar structure of the main part of the semiconductor device.

FIG. 3A is a schematic view illustrating the cross-sectional structure of the main part of a semiconductor device according to a second embodiment of the invention, and FIG. 3B is a schematic diagram showing the variation of doping concentration along the depth in the semiconductor device.

FIG. 4A is a schematic view illustrating the cross-sectional structure of the main part of a semiconductor device according to a third embodiment of the invention, and FIG. 4B is a schematic diagram showing the variation of doping concentration along the depth in the semiconductor device.

FIG. 5 is a schematic view illustrating the cross-sectional structure of the main part of a semiconductor device according to a fourth embodiment of the invention.

FIGS. 6 to 8 are process cross-sectional views illustrating the main part of a process of manufacturing a semiconductor device according to the fourth embodiment.

FIG. 9 is a schematic view illustrating the cross-sectional structure of the main part of a semiconductor device according to a fifth embodiment of the invention.

FIG. 10 is a schematic view illustrating the cross-sectional structure of the main part of a semiconductor device according to a sixth embodiment of the invention.

FIG. 11 is a schematic view illustrating the planar structure of the main part of the semiconductor device.

FIGS. 12 to 20 are process cross-sectional views illustrating the main part of a process of manufacturing a semiconductor device according to the sixth embodiment of the invention.

FIG. 21 is a schematic view illustrating the cross-sectional structure of the main part of a semiconductor device according to a comparative example.

FIG. 22 is a graph showing the relationship between the insulating film thickness of the terminal section and the device breakdown voltage.

FIG. 23 is a graph showing the relationship between the breakdown voltage and the ratio of the insulating film thickness of the terminal section to the insulating film thickness of the source contact portion.

FIG. 24 is a graph showing the relationship between the ratio of the insulating film thickness of the terminal section to the insulating film thickness of the source contact portion and the aspect ratio of the source contact hole.

FIG. 25 is a schematic view illustrating the cross-sectional structure of the main part of a semiconductor device according to a seventh embodiment of the invention.

FIG. 26 is a schematic view illustrating the cross-sectional structure of the main part of a semiconductor device according to an eighth embodiment of the invention,

FIG. 27 is a schematic view illustrating the cross-sectional structure of the main part of a semiconductor device according to a ninth embodiment of the invention.

FIG. 28 is a schematic view illustrating the cross-sectional structure of the main part of a semiconductor device according to a tenth embodiment of the invention.

FIG. 29 is a schematic view illustrating the cross-sectional structure of the main part of a semiconductor device according to an eleventh embodiment of the invention.

FIGS. 30 to 34 are process cross-sectional views illustrating the main part of a process of manufacturing a semiconductor device according to the eleventh embodiment of the invention.

FIG. 35 is a schematic view illustrating the cross-sectional structure of the main part of a semiconductor device according to a twelfth embodiment of the invention.

FIG. 36 is a schematic view illustrating the cross-sectional structure of the main part of a semiconductor device according to a thirteenth embodiment of the invention.

FIG. 37 is a schematic view illustrating the cross-sectional structure of the main part of a semiconductor device according to a fourteenth embodiment of the invention.

FIG. 38 is a schematic view illustrating the cross-sectional structure of the main part of a semiconductor device according to a fifteenth embodiment of the invention.

### DETAILED DESCRIPTION OF THE INVENTION

Embodiments of the invention will now be described with reference to the drawings. The following embodiments are illustrated assuming the first conductivity type as n-type and the second conductivity type as p-type. Like elements in the drawings are marked with like reference numerals.

### First Embodiment

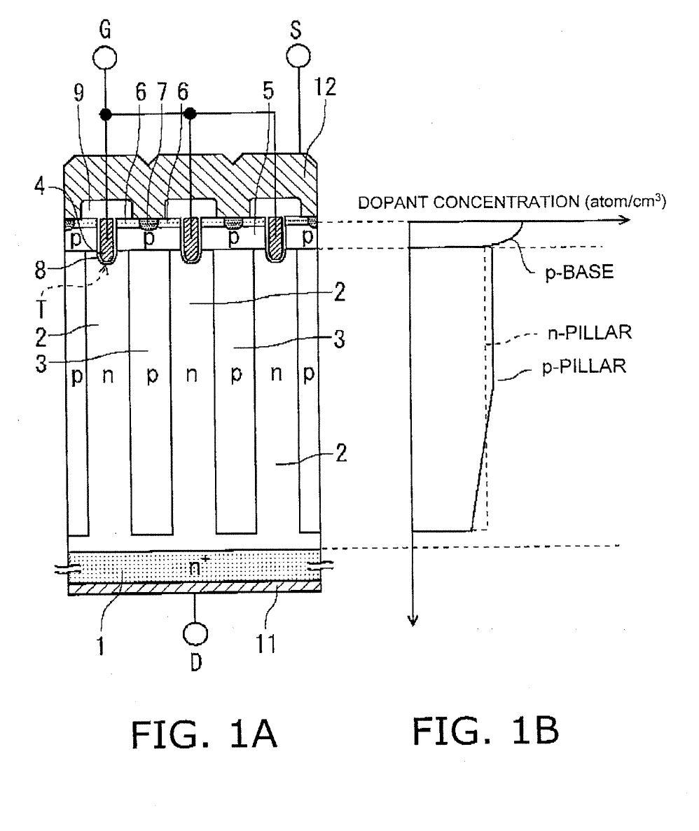

FIG. 1A is a schematic view illustrating the cross-sectional structure of the main part of a semiconductor device according to a first embodiment of the invention, and FIG. 1B is a schematic diagram showing the variation of doping concentration along the depth in the semiconductor device.

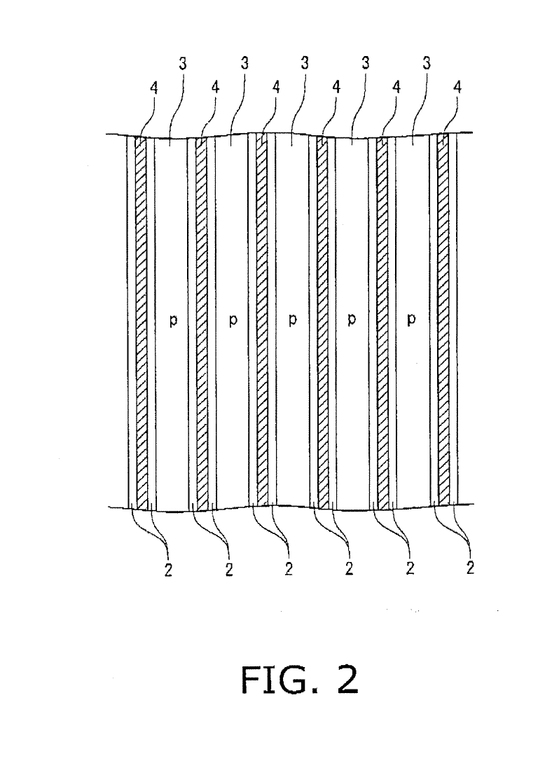

FIG. 2 is a schematic view illustrating the planar structure of the main part of the semiconductor device.

For example, first semiconductor pillar regions 2 of n-type silicon (hereinafter also simply referred to as “n-type pillar regions”) and second semiconductor pillar regions 3 of p-type silicon (hereinafter also simply referred to as “p-type pillar regions”) are juxtaposed in a striped configuration on a major surface of a semiconductor layer 1 of highly doped n⁺-type silicon.

The n-type pillar regions 2 and the p-type pillar regions 3 constitute a so-called superjunction structure. That is, the n-type pillar region 2 and the p-type pillar region 3 are adjacent to each other to form a pn junction.

Such a superjunction structure is obtained by, for example, multiple repetition of a process where ion implantation and diffusion are applied to a high-resistance epitaxial layer to selectively form an n-type and p-type buried layer, followed by laminating thereon another high-resistance epitaxial layer, and ion implantation and diffusion are applied again to the latter high-resistance layer to selectively form an n-type and p-type buried layer. Alternatively, the superjunction structure is also obtained by forming a trench in an n-type semiconductor layer followed by buried growth of a p-type semiconductor layer in the trench.

On the p-type pillar region 3 is provided a base region (first semiconductor region) 5 of p-type silicon in contact with the p-type pillar region 3. Part of the base region 5 forms a pn junction with the upper surface of the n-type pillar region 2. A source region (second semiconductor region) 6 of n⁺-type silicon is selectively provided in the surface portion of the base region 5. In the surface portion of the base region 5, a p⁺-type base region 7 is provided between the source regions 6.

A trench T is formed from the surface side of the source region 6 toward the n-type pillar region 2. The trench T is adjacent to the source region 6 and the base region 5, and the bottom of the trench T reaches the n-type pillar region 2. A gate electrode (control electrode) 4 of polysilicon, for example, is buried inside the trench T via an insulating film 8.

An insulating film 9 is provided on the trench T, the gate electrode 4, and part of the source region 6. A source electrode (second main electrode) 12 is provided between the insulating films 9 on the surface of the source region 6 and the p⁺-type base region 7. The source electrode 12 is in contact with the source region 6 and the p⁺-type base region 7. A drain electrode (first main electrode) 11 is provided on the side opposite to the major surface of the n⁺-type semiconductor layer 1.

When a prescribed voltage is applied to the gate electrode 4, a channel is formed in a portion of the base region 5 that is opposed to the gate electrode 4 via the insulating film 8 and allows conduction between the source region 6 and the n-type pillar region 2. As a result, a main current path is formed between the drain electrode 11 and the source electrode 12 through the source region 6, the n-type pillar region 2, and the n⁺-type semiconductor layer 1. Thus the path between the electrodes 11 and 12 is turned into the ON state.

FIG. 1B shows a doping concentration profile (thick solid line) along the depth (the direction from the source electrode 12 toward the drain electrode 11) of the p-type pillar region 3 and a doping concentration profile (dashed line) along the depth (the direction from the source electrode 12 toward the drain electrode 11) of the n-type pillar region 2. The “doping concentration” used herein refers to the doping concentration in the vertical direction at the center of the width of each pillar region.

As shown in FIG. 1B, in this embodiment, the doping concentration in the p-type pillar region 3 is substantially constant up to the substantially intermediate portion in the direction from the source electrode 12 toward the drain electrode 11 and gradually decreases from this substantially intermediate portion toward the drain electrode 11. The doping concentration in the n-type pillar region 2 is substantially constant in the direction from the source electrode 12 toward the drain electrode 11. From the upper portion (the portion on the source electrode 12 side) of the n-type pillar region 2 and the p-type pillar region 3 to the portion where the doping concentration in the p-type pillar region 3 begins to decrease, the doping concentration is slightly higher in the p-type pillar region 3 than in the n-type pillar region 2. In the lower portion (the portion on the drain electrode 11 side) of the n-type pillar region 2 and the p-type pillar region 3, the doping concentration becomes higher in the n-type pillar region 2 than in the p-type pillar region 3.

That is, the doping concentration in the p-type pillar region 3 is sloped along the depth from the substantially intermediate portion to the lower portion (the portion on the drain electrode 11 side) and is made substantially constant without slope from the upper portion (the portion on the source electrode 12 side) to the substantially intermediate portion. Hence, in the upper portion (the portion on the source electrode 12 side) of the pillar region, the degree of p-pillar richness (the state of the p-type pillar region 3 being more highly doped than the n-type pillar region 2) is reduced. Thus, even if the pillar region is downscaled, it is possible to prevent the depletion layer from spreading to the n-type pillar region 2 and to reduce the spreading resistance to electrons between the channel and the n-type pillar region 2.

Even when the doping concentration in the n-type pillar region 2 serving as a current path is increased to reduce the ON resistance, the n-type pillar region 2 and the p-type pillar region 3 can be downscaled to facilitate complete depletion during OFF state, that is, to improve the tradeoff between the ON resistance and the breakdown voltage.

Below the substantially intermediate portion in the direction from the source electrode 12 toward the drain electrode 11, the doping concentration in the p-type pillar region 3 is sloped so as to gradually decrease from the substantially intermediate portion toward the drain electrode 11 as in Japanese Patent No. 3634830 described above. Therefore the decrease of breakdown voltage due to the difference of the amount of dopant (amount of imbalance) between the p-type pillar region 3 and the n-type pillar region 2 can be reduced to provide a wide process margin.

Furthermore, below the substantially intermediate portion, the imbalance of doping concentration between the p-type pillar region 3 and the n-type pillar region 2 increases, and hence the electric field concentration during OFF state is maximized in the vicinity of the substantially intermediate portion. Therefore, as compared with the case where the doping concentration in each of the p-type pillar region 3 and the n-type pillar region 2 is made substantially constant along the depth, the electric field concentration is alleviated in the vicinity of the trench gate bottom where the electric field is likely to concentrate because of the large curvature. This prevents carrier injection to the gate insulating film 8, thereby enhancing the reliability.

In the following, other embodiments of the invention are described. Elements similar to those described earlier are marked with the same reference numerals and not described in detail.

### Second Embodiment

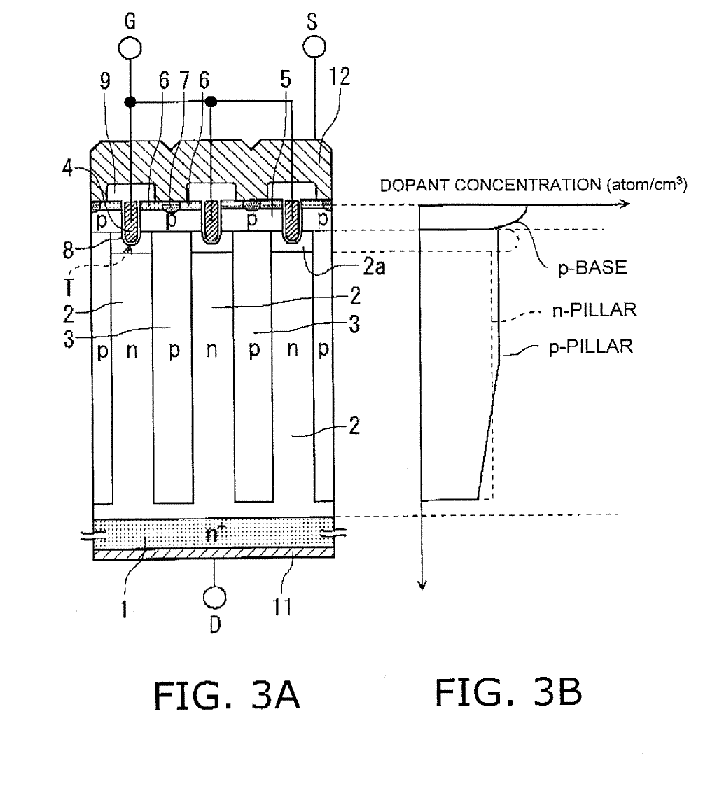

FIG. 3A is a schematic view illustrating the cross-sectional structure of the main part of a semiconductor device according to a second embodiment of the invention, and FIG. 3B is a schematic diagram showing the variation of doping concentration along the depth in the semiconductor device.

This embodiment is similar to the first embodiment in that the doping concentration in the p-type pillar region 3 is substantially constant up to the substantially intermediate portion in the direction from the source electrode 12 toward the drain electrode 11 and gradually decreases from this substantially intermediate portion toward the drain electrode 11. In this embodiment again, the “doping concentration” refers to the doping concentration in the vertical direction at the center of the width of each pillar region.

On the other hand, in contrast to the first embodiment, the upper portion 2a of the n-type pillar region 2 in contact with the base region 5 and the trench T is more highly doped than the other portion of the n-type pillar region 2. That is, in the n-type pillar region 2, the portion 2a between the trench T and the p-type pillar region 3 has a higher doping concentration than the other portion. The doping concentration in the portion 2a is higher than the doping concentration in the upper portion of the p-type pillar region 3 adjacent to this portion 2a. In the n-type pillar region 2, the doping concentration in the portion other than the highly doped (upper) portion 2a is substantially constant as in the first embodiment.

By increasing the doping concentration in the upper portion 2a of the n-type pillar region 2, the spreading resistance to electrons between the channel and the n-type pillar region 2 can be reduced, and thereby the ON resistance can be reduced.

### Third Embodiment

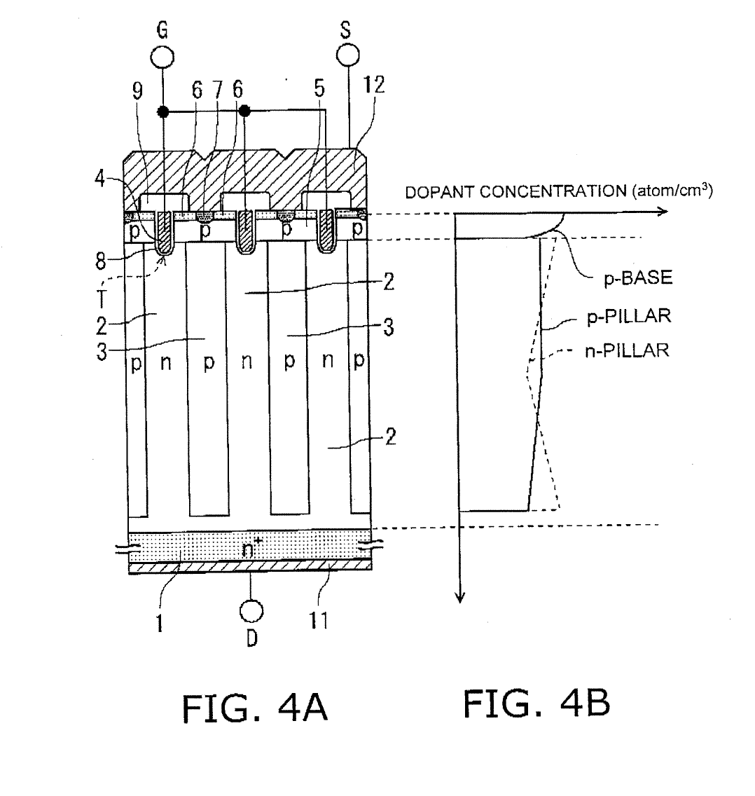

FIG. 4A is a schematic view illustrating the cross-sectional structure of the main part of a semiconductor device according to a third embodiment of the invention, and FIG. 4B is a schematic diagram showing the variation of doping concentration along the depth in the semiconductor device, in this embodiment again, the “doping concentration” refers to the doping concentration in the vertical direction at the center of the width of each pillar region.

This embodiment is similar to the first embodiment in that the doping concentration in the p-type pillar region 3 is substantially constant up to the substantially intermediate portion in the direction from the source electrode 12 toward the drain electrode 11 and gradually decreases from this substantially intermediate portion toward the drain electrode 11, The profile of the doping concentration in the n-type pillar region 2 along the depth is different from that in the first embodiment.

The doping concentration in the n-type pillar region 2 gradually decreases up to the substantially intermediate portion in the direction from the source electrode 12 toward the drain electrode 11 and gradually increases from the substantially intermediate portion toward the drain electrode 11. In the upper portion (the portion on the source electrode 12 side) of the n-type pillar region 2 and the p-type pillar region 3, the doping concentration is higher in the n-type pillar region 2 than in the p-type pillar region 3. Likewise, in the lower portion (the portion on the drain electrode 11 side) of the n-type pillar region 2 and the p-type pillar region 3, the doping concentration is higher in the n-type pillar region 2 than in the p-type pillar region 3. The doping concentration in the n-type pillar region 2 is minimized at the substantially intermediate portion in the direction from the source electrode 12 toward the drain electrode 11, and at this substantially intermediate portion, the doping concentration is higher in the p-type pillar region 3 than in the n-type pillar region 2.

According to this embodiment, at the substantially intermediate portion in the direction from the source electrode 12 toward the drain electrode 11, the imbalance of doping concentration between the p-type pillar region 3 and the n-type pillar region 2 increases, and hence the electric field concentration during OFF state is maximized in the vicinity of the substantially intermediate portion. Therefore the electric field concentration is alleviated in the vicinity of the trench gate bottom where the electric field is likely to concentrate because of the large curvature. This prevents carrier injection to the gate insulating film 8, thereby enhancing the reliability.

### Fourth Embodiment

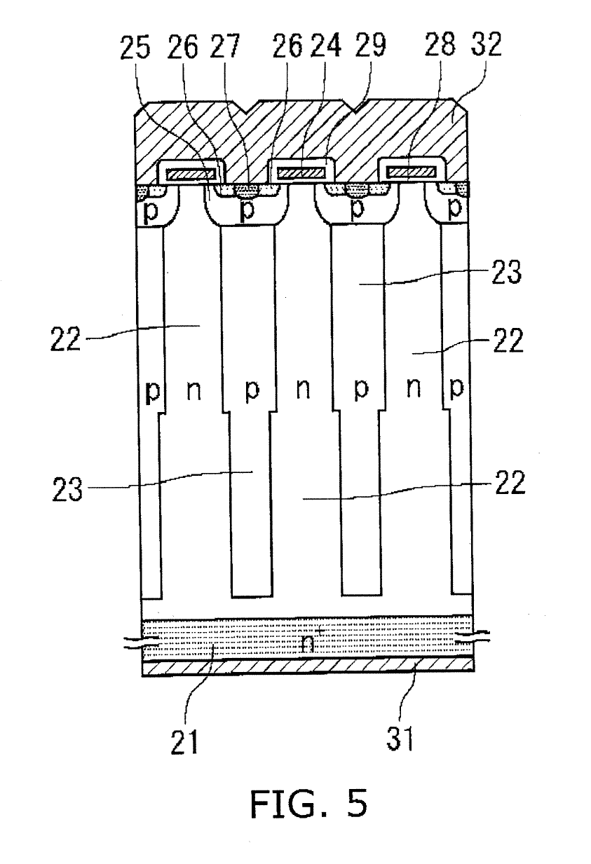

FIG. 5 is a schematic view illustrating the cross-sectional structure of the main part of a semiconductor device according to a fourth embodiment of the invention.

For example, n-type pillar regions (first semiconductor pillar regions) 22 of n-type silicon and p-type pillar regions (second semiconductor pillar regions) 23 of p-type silicon are juxtaposed in a striped configuration on a major surface of a semiconductor layer 21 of highly doped n⁺-type silicon. The n-type pillar regions 22 and the p-type pillar regions 23 constitute a so-called superjunction structure. That is, the n-type pillar region 22 and the p-type pillar region 23 are adjacent to each other to form a pn junction.

The width of the p-type pillar region 23 (the width in the direction along which the n-type pillar region 22 and the p-type pillar region 23 are juxtaposed) is narrowed stepwise from the source electrode (second main electrode) 32 toward the drain electrode (first main electrode) 31. That is, the width of the p-type pillar region 23 is narrowed stepwise along the depth. Conversely, the width of the n-type pillar region 22 adjacent to the p-type pillar region 23 is expanded stepwise from the source electrode 32 toward the drain electrode 31 (along the depth).

In this embodiment, for example, a step is formed at the substantially intermediate portion along the depth of the junction between the n-type pillar region 22 and the p-type pillar region 23 (the substantially intermediate portion in the direction from the source electrode 32 toward the drain electrode 31). In the example illustrated in FIG. 5, the width of each of the n-type pillar region 22 and the p-type pillar region 23 is varied in two levels. However, the width may be varied in three or more levels.

On the p-type pillar region 23 is provided a base region (first semiconductor region) 25 of p-type silicon in contact with the p-type pillar region 23. The base region 25 is adjacent to the upper portion of the n-type pillar region 22. A source region (second semiconductor region) 26 of n⁺-type silicon is selectively provided in the surface portion of the base region 25. In the surface portion of the base region 25, a p⁺-type base region 27 is provided between the source regions 26.

An insulating film 28 is provided on the portion extending from the n-type pillar region 22 through the base region 25 to the source region 26. A gate electrode (control electrode) 24 is provided on the insulating film 28 and covered with an insulating film 29.

A source electrode (second main electrode) 32 is provided on part of the source region 26 and on a portion of the base region 25 between the source regions 26, and the source region 26 is electrically connected to the source electrode 32. A drain electrode (first main electrode) 31 is provided on the side opposite to the major surface of the n⁺-type semiconductor layer 21.

When a prescribed voltage is applied to the gate electrode 24, a channel is formed in the vicinity of the surface of the base region 25 therebelow and allows conduction between the source region 26 and the n-type pillar region 22. As a result, a main current path is formed between the drain electrode 31 and the source electrode 32 through the source region 26, the n-type pillar region 22, and the n⁺-type semiconductor layer 21. Thus the path between the electrodes 31 and 32 is turned into the ON state.

Next, an example method of manufacturing a semiconductor device according to this embodiment is described.

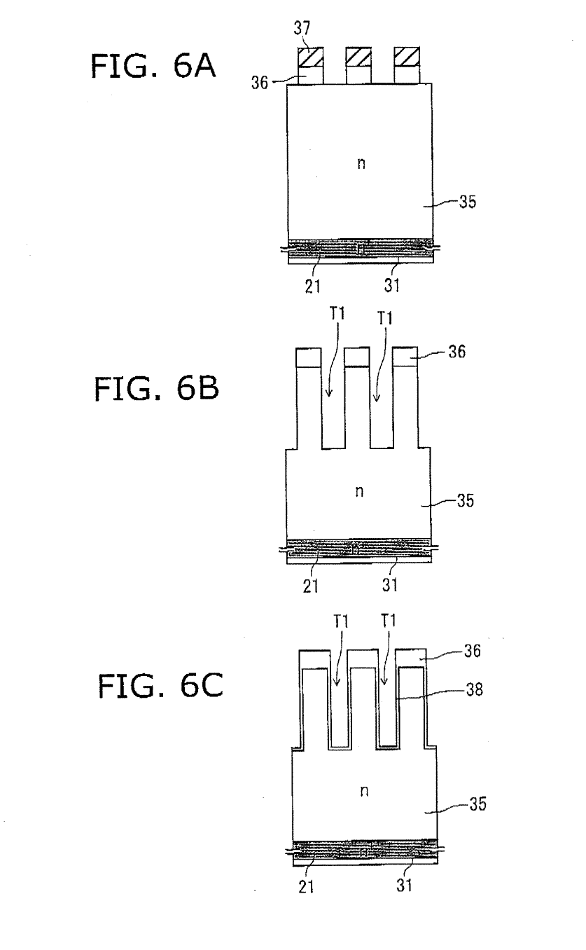

FIGS. 6 to 8 are process cross-sectional views illustrating the main part of a process of manufacturing a semiconductor device according to this embodiment.

First, as shown in FIG. 6A, a mask 36 of silicon oxide, for example, is patterned using a resist 37 on a major surface of a first semiconductor layer (of n-type silicon, for example) 35 with an n⁺-type semiconductor layer 21 being formed on the side opposite to the major surface. While a drain electrode 31 is formed on the backside of the n⁺-type semiconductor layer 21, the drain electrode 31 may be formed in a later step.

Next, the first semiconductor layer 35 is etched using the mask 36 by the RIE (Reactive Ion Etching) technique, for example. This etching is conducted halfway through the first semiconductor layer 35 (from the major surface side to the substantially intermediate portion, for example). Thus, as shown in FIG. 6B, a plurality of trenches T1 extending from the major surface side of the first semiconductor layer 35 to the substantially intermediate portion are formed.

Next, as shown in FIG. 6C, with the mask 36 being left, an insulating film (oxide film) 38 is formed on the inner wall surface (sidewall surface and bottom surface) of the trench T1 by thermal oxidation, for example.

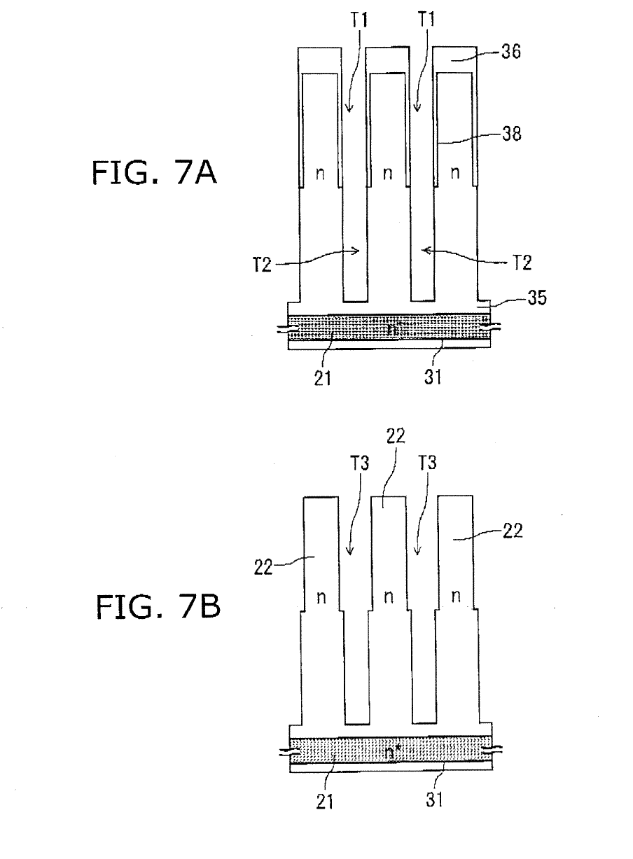

Next, with the mask 36 and the insulating film 38 being left, the first semiconductor layer 35 below the trench T1 is etched by the RIE technique, for example. Thus, as shown in FIG. 7A, the insulating film 38 on the bottom surface of the trench T1 is removed, and a trench T2 extending from the trench T1 is formed in the first semiconductor layer 35.

Next, the mask 36 and the insulating film 38 formed on the sidewall surface of the trench T1 are removed. Thus, as shown in FIG. 7B, a trench T3 in a stepped shape is formed with a width that is narrowed stepwise from the opening toward the bottom. Contrary to the trench T3, an n-type pillar region 22 in a stepped shape having a width that is expanded stepwise from the opening toward the bottom is formed adjacent to the trench T3.

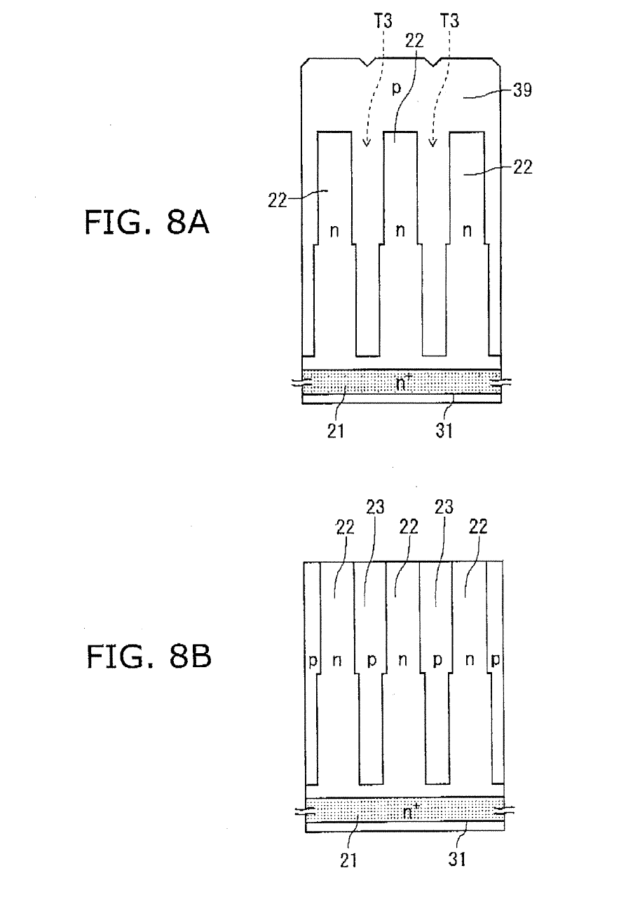

Next, as shown in FIG. 8A, a second semiconductor layer (of p-type silicon, for example) 39 is deposited on the entire surface by the CVD (Chemical Vapor Deposition) technique so as to fill the trench T3. Then, as shown in FIG. 8B, the second semiconductor layer 39 above the trench T3 is planarized by etching back or polishing, for example, and the upper surface of the n-type pillar region 22 is exposed. Thus a superjunction structure is obtained, which is composed of n-type pillar regions 22 and p-type pillar regions 23 alternately and adjacently juxtaposed in the width direction substantially parallel to the major surface of the n⁺-type semiconductor layer 21.

Subsequently, a gate insulating film 28 and a gate electrode 24 are formed and then used as a mask for ion implantation, followed by diffusion of the implanted ions. Thus a p-type base region 25 is formed in the surface portion of the p-type pillar region 23. Then, in the surface portion of the base region 25, an n⁺-type source region 26 and a p⁺-type base region 27 are selectively formed, and a source electrode 32 is formed in contact therewith.

In a semiconductor device having a superjunction structure where the minimum dimension of repetition (cell pitch) of the p/n-pillar region is 5 μm, for example, the p/n-pillar region requires a thickness of about 17 μm for achieving breakdown voltage VB=300 V. Assuming that half the cell pitch on one side is occupied by the p-type pillar region, it is required to form a p-type pillar region having an aspect ratio of about 6 to 8. Such a semiconductor region having a narrow width and a high aspect ratio can be formed by a method of, for example, forming a deep trench from the surface side of an epitaxially grown layer and filling the trench with a semiconductor having a conductivity type different from that of the epitaxially grown layer. However, in this case, the high aspect ratio of the trench results in poor performance of filling the trench with semiconductor. That is, before the trench is completely filled with semiconductor, the amount of deposits on the sidewall in the vicinity of the opening of the trench is likely to increase, thereby clogging the opening.

However, in this embodiment, the trench to be filled with the p-type pillar region 23 is formed by etching in two stages to have a stepped shape with the opening side being wider. Therefore, when the trench is filled with the p-type pillar region 23, clogging in the vicinity of the trench opening is prevented, thereby improving the performance of filling the trench with the p-type pillar region 23. Thus, even if the pillar region is downscaled and the trench has a high aspect ratio, it is possible to avoid the failure of filling the trench with the p-type pillar region 23, thereby ensuring the reliability.

The superjunction structure can be formed with good mass productivity by repeating multiple times the step of selectively forming an n-type and p-type buried layer by ion implantation and diffusion in a high-resistance epitaxially grown layer. However, in this case, the high-resistance epitaxially grown layer laminated on the n-type and p-type buried layer needs to have such a thickness that the n-type and p-type layer formed in this high-resistance epitaxially grown layer can be connected to the underlying n-type and p-type layer formed in the high-resistance epitaxially grown layer in the previous step. Hence a high aspect ratio involves a longer diffusion time and/or an increased number of iterations of epitaxial growth and ion implantation.

### Fifth Embodiment

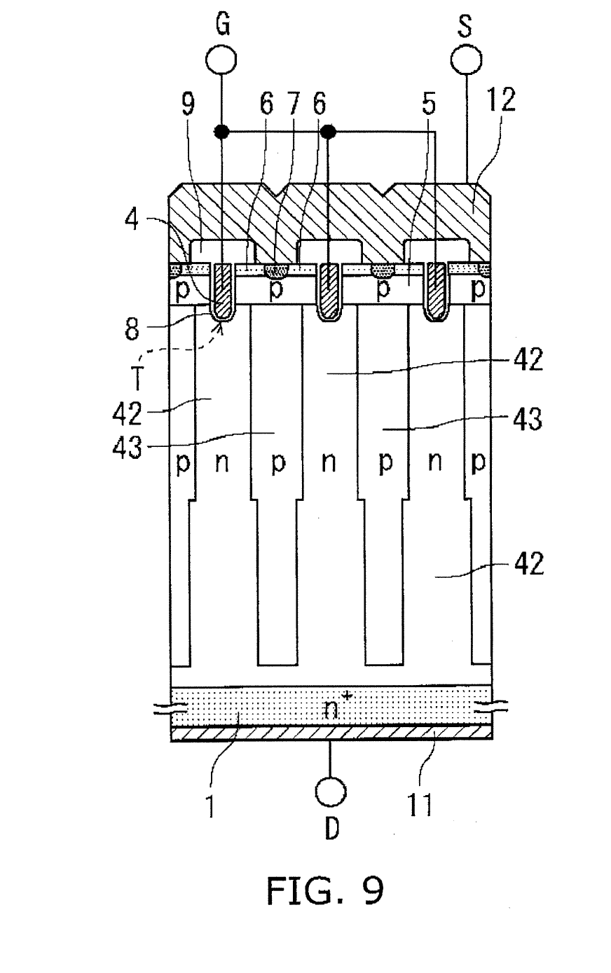

FIG. 9 is a schematic view illustrating the cross-sectional structure of the main part of a semiconductor device according to a fifth embodiment of the invention. In this embodiment again, the “doping concentration” refers to the doping concentration in the vertical direction at the center of the width of each pillar region.

This embodiment is an application of the fourth embodiment to one of the first to third embodiment. More specifically, the doping concentration in the p-type pillar region 43 is substantially constant up to the substantially intermediate portion in the direction from the source electrode 12 toward the drain electrode 11 and gradually decreases from this substantially intermediate portion toward the drain electrode 11. Furthermore, the width of the p-type pillar region 43 (the width of the trench filled with the p-type pillar region 43) is narrowed stepwise from the source electrode 12 toward the drain electrode 11.

Therefore, in this embodiment again, even if the p-type pillar region 43 is downscaled and the trench has a high aspect ratio, it is possible to avoid the failure of filling the trench with the p-type pillar region 43, thereby ensuring the reliability. Furthermore, the degree of p-pillar richness can be reduced on the source electrode 12 side to reduce the spreading resistance to electrons between the channel and the n-type pillar region 42. Moreover, below the substantially intermediate portion in the direction from the source electrode 12 toward the drain electrode 11, the doping concentration in the p-type pillar region 43 is sloped so as to gradually decrease from the substantially intermediate portion toward the drain electrode 11. Therefore the decrease of breakdown voltage due to the difference of the amount of dopant (amount of imbalance) between the p-type pillar region 43 and the n-type pillar region 42 can be reduced to provide a wide process margin.

Furthermore, a step is formed at the substantially intermediate portion in the direction from the source electrode 12 toward the drain electrode 11, where the electric field is likely to concentrate. Therefore the electric field concentration is alleviated in the vicinity of the trench gate bottom. This prevents carrier injection to the gate insulating film 8, thereby enhancing the reliability.

### Sixth Embodiment

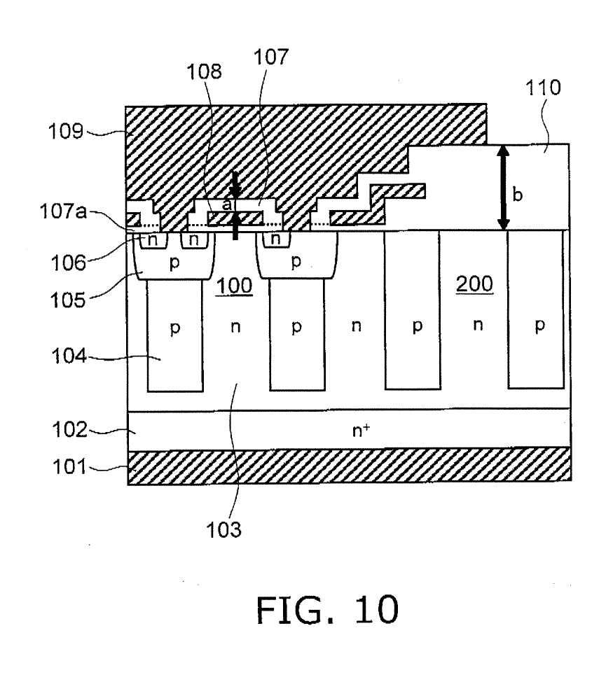

FIG. 10 is a schematic view illustrating the cross-sectional structure of the main part of a semiconductor device according to a sixth embodiment of the invention.

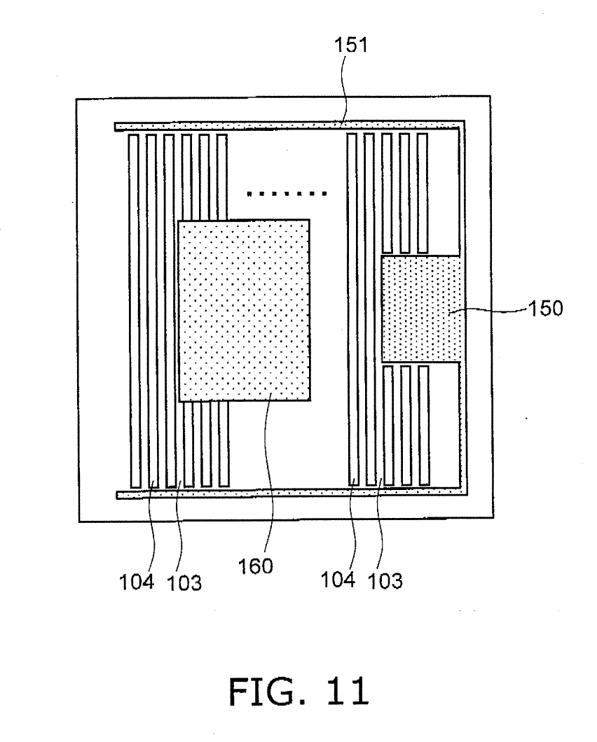

FIG. 11 is a schematic view illustrating the planar structure of the main part of the semiconductor device.

First pillar regions 103 of n-type silicon (hereinafter also simply referred to as “n-type pillar regions”) and second pillar regions 104 of p-type silicon (hereinafter also simply referred to as “ptype pillar regions”) are juxtaposed in a striped configuration, for example, on a major surface of a semiconductor layer 102 of highly doped n⁺-type silicon.

The n-type pillar regions 103 and the p-type pillar regions 104 constitute a so-called superjunction structure. That is, the n-type pillar region 103 and the p-type pillar region 104 are adjacent to each other to form a pn junction. FIG. 10 illustrates a cross-sectional configuration where the superjunction structure is provided not only in the device section 100 but also in the terminal section 200. However, the superjunction structure may not be provided in the terminal section 200.

On the p-type pillar region 104 is provided a base region (first semiconductor region) 105 of p-type silicon in contact with the p-type pillar region 104. Like the p-type pillar region 104, the base region 105 is also adjacent to the n-type pillar region 103 to form a pn junction. A source region (second semiconductor region) 106 of n⁺-type silicon is selectively provided in the surface of the base region 105.

A gate insulating film (first insulating film) 107a is provided on the portion extending from the n-type pillar region 103 through the base region 105 to the source region 106. A gate electrode (control electrode) 108 is provided on the gate insulating film 107a. A second insulating film 107 covers the periphery and upper surface of the gate electrode 108.

A source electrode (second main electrode) 109 is provided on part of the source region 106 and on a portion of the base region 105 between the source regions 106. The source region 106 is electrically connected to the source electrode 109. A drain electrode (first main electrode) 101 is provided on the side opposite to the major surface of the semiconductor layer 102.

Furthermore, as shown in FIG. 11, a gate electrode pad 150 connected to the gate electrode 108 through a gate interconnect 151 and a source electrode pad 160 connected to the source electrode 109 are formed on the device surface.

The foregoing components are main elements of a device section 100 in the semiconductor device. When a prescribed control voltage is applied to the gate electrode 108, a channel is formed in the vicinity of the surface of the base region 105 immediately below the gate electrode 108 and allows conduction between the source region 106 and the n-type pillar region 103. As a result, a main current path is formed between the source electrode 109 and the drain electrode 101 through the source region 106, the n-type pillar region 103, and the semiconductor layer 102. Thus the path between the source electrode 109 and the drain electrode 101 is turned into the ON state.

In the terminal section 200 adjacent to the device section 100, a field insulating film (third insulating film) 110 is formed on the major surface of the semiconductor layer 102. The thickness a of the second insulating film 107 on the gate electrode 108 is related to the thickness b of the field insulating film 110 as (b/15)≦a≦(b/3).

Next, an example method of manufacturing a semiconductor device according to this embodiment is described.

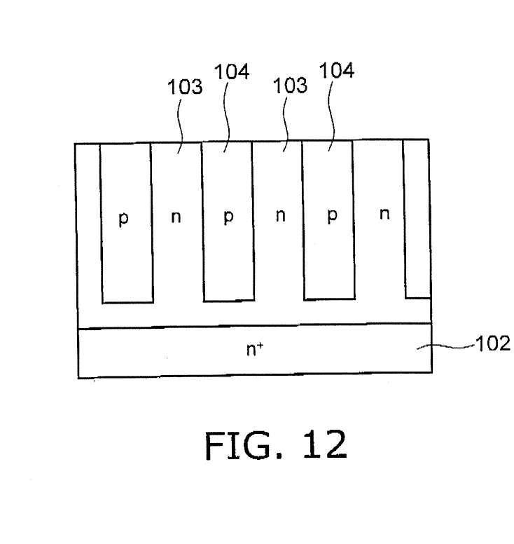

FIGS. 12 to 20 are process cross-sectional views illustrating the main part of a process of manufacturing a semiconductor device according to this embodiment.

First, as shown in FIG. 12, a superjunction structure composed of n-type pillar regions 103 and p-type pillar regions 104 is formed on a major surface of an n⁺-type silicon semiconductor layer 102. The superjunction structure can be obtained by, for example, a process of multiple repetition of ion implantation and buried epitaxial growth. It is also possible to use a method of forming a trench in an n-type semiconductor layer followed by buried growth of a p-type semiconductor layer in the trench, or a method of forming a trench followed by ion implantation into the trench sidewall.

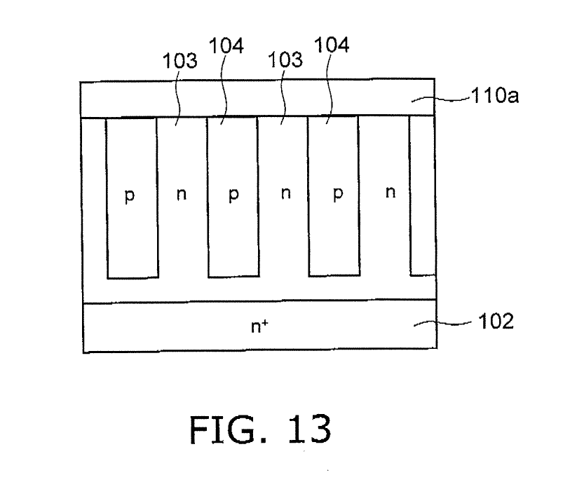

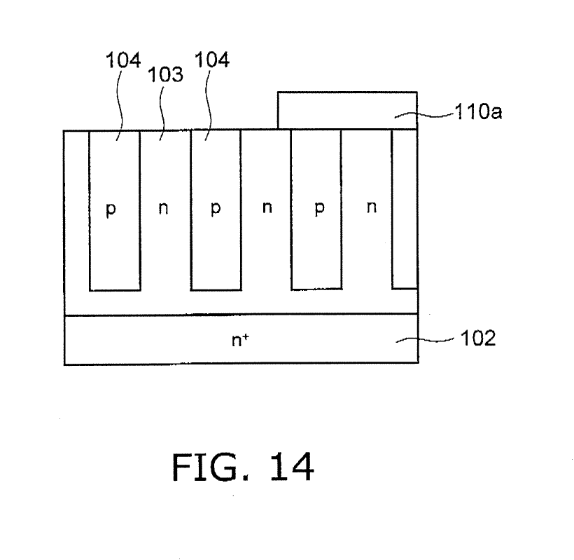

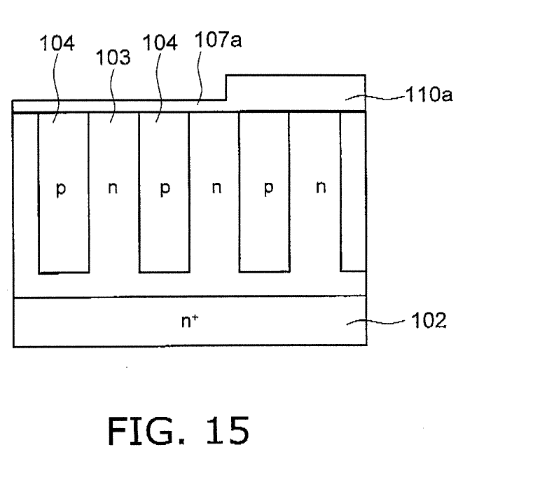

After the superjunction structure is formed, as shown in FIG. 13, an insulating film (silicon oxide film) 110a is formed on the surface by thermal oxidation. Then, as shown in FIG. 14, only the insulating film 110a of the device section is etched away. Then, as shown in FIG. 15, a gate insulating film (silicon oxide film) 107a is formed on the surface of the device section by thermal oxidation.

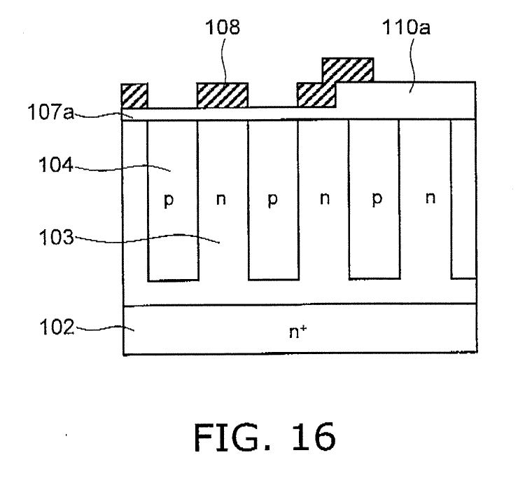

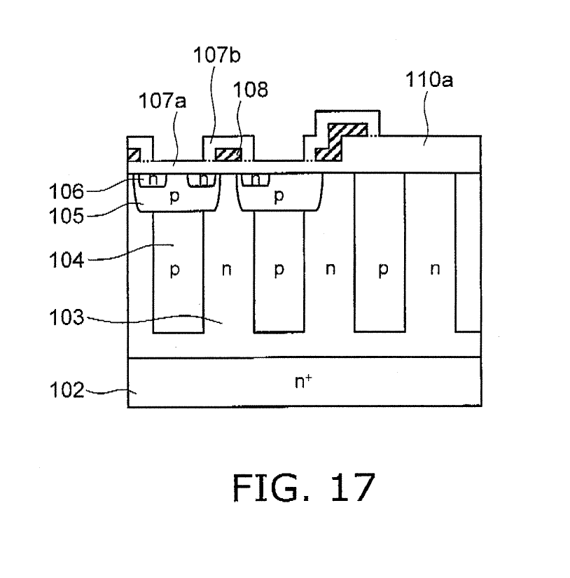

Subsequently, polysilicon 108, for example, is deposited as a gate electrode material on the entire surface. Then, as shown in FIG. 16, the polysilicon 108 is patterned by lithography and etching. Subsequently, as shown in FIG. 17, a thermal oxide film 107b of the polysilicon 108 is formed. Then a base region 105 and a source region 106 are formed by ion implantation and diffusion.

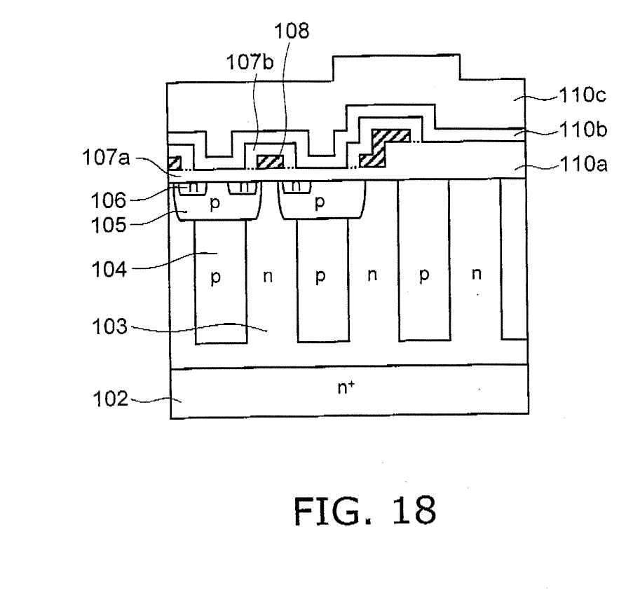

Subsequently, as shown in FIG. 18, a silicon nitride film 110b is deposited on the gate insulating film 107a, the thermal oxide film 107b, and the insulating film 110a by chemical vapor deposition, for example. A silicon oxide film 110c is further deposited on the silicon nitride film 110b, again by chemical vapor deposition.

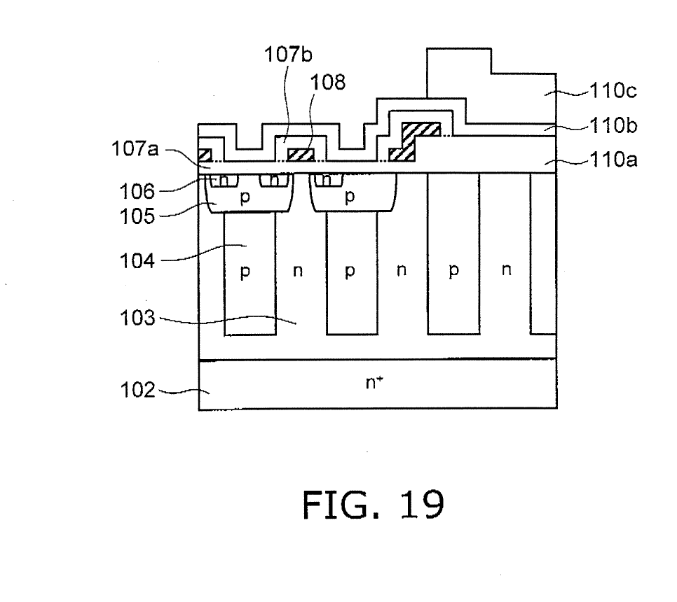

Then, as shown in FIG. 19, the silicon oxide film 110c of the device section is selectively removed by lithography and etching. The difference in material between the silicon nitride film 110b and the silicon oxide film 110c enables only the silicon oxide film 110c in the device section to be selectively etched by wet etching or the like. That is, the silicon nitride film 110b functions as an etch stop layer. Thus it is possible to form a structure with a thin insulating film in the device section and a thick insulating film in the terminal section on the gate electrode 108, only the thermal oxide films (the thermal oxide film 107b and the silicon nitride film 110b) are formed, and no deposited film (silicon oxide film 110c) is formed.

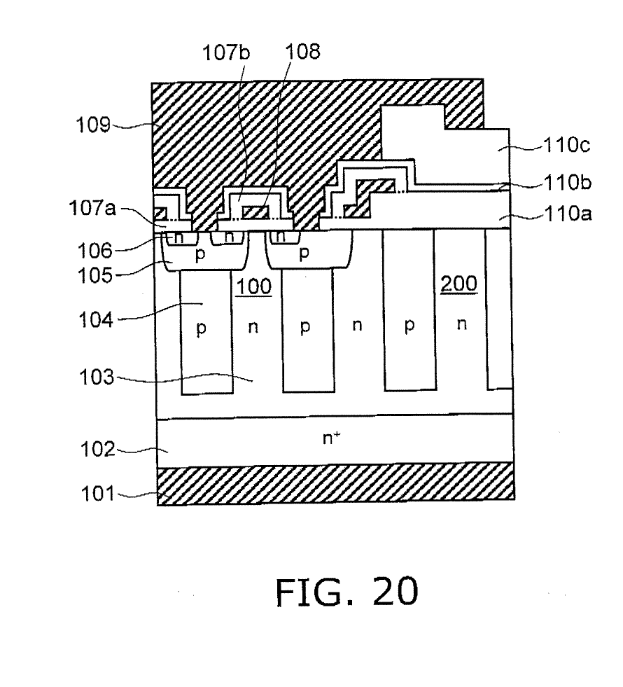

Then a contact hole is opened through the gate insulating film 107a and the silicon nitride film 110b of the source contact portion. As shown in FIG. 20, a source electrode 109 is formed so as to fill the contact hole. Furthermore, a drain electrode 101 is formed on the backside of the semiconductor layer 102.

As described above, according to this embodiment, the insulating film of the terminal section has a thickness required to ensure the breakdown voltage, while only the insulating film of the device section is thinned. Thus, without the deterioration of the burying performance of source metal due to the increased aspect ratio of the source contact hole, the source contact width can be reduced to obtain a semiconductor device having a fine MOS gate structure that can follow the downscaling of the superjunction structure. As a result, the overall ON resistance of the device can be further reduced while maintaining high breakdown voltage.

As described earlier, when the lateral period of p/n-pillar regions of the superjunction structure is narrowed, the cell pitch of the MOS gate structure must also be narrowed for avoiding the resistance increase. The MOS cell pitch is the sum of the gate length, the gate-source offset length, and the source contact width.

It is possible to reduce the gate length by fine patterning using lithography. However, the spacing between the base regions is narrowed, and the ON resistance is increased. On the other hand, reduction of the gate-source offset length increases the possibility of gate-source short, thereby decreasing the gate-source breakdown voltage and the yield. Thus reduction of the source contact width is effective for reducing the MOS cell pitch without deteriorating the characteristics.

Reduction of the source contact width results in increasing the aspect ratio of the source contact hole (insulating film thickness of the source contact portion/source contact width). When this aspect ratio is increased, the performance of burying the source electrode into the contact hole is deteriorated, and the source electrode resistance is increased. Thus the aspect ratio of the source contact hole is preferably 0.7 or less. The portion of the insulating film where the source contact hole is opened must be thinned for narrowing the contact width without increasing the aspect ratio.

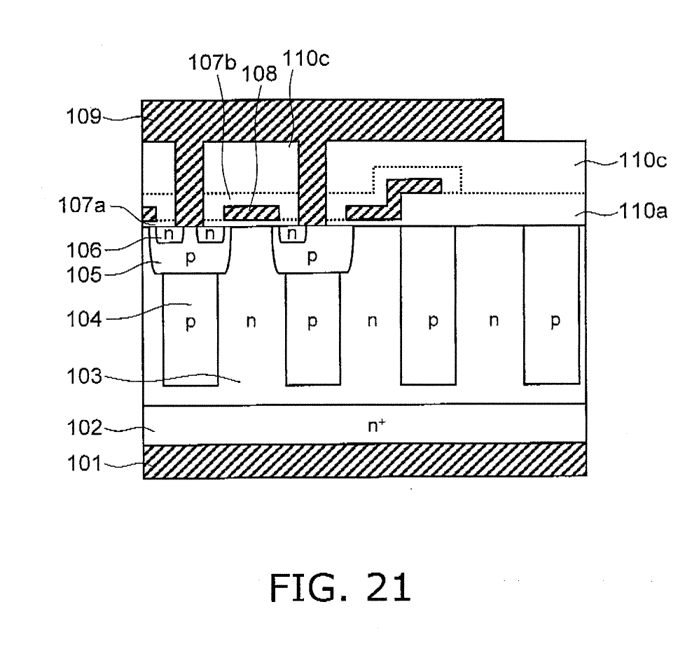

FIG. 21 is a schematic view illustrating the cross-sectional structure of the main part of a semiconductor device according to a comparative example. The field insulating film of the terminal section is composed of a thermal oxide film (silicon oxide film) 110a and a deposited film (silicon oxide film) 110c deposited by chemical vapor deposition or the like. A thermal oxide film (silicon oxide film) 107b is formed on the gate electrode 108 in the device section (MOS cell section) by thermally oxidizing the gate electrode 108. The deposited film 110c provided in the terminal section is deposited also on the MOS cell section during its formation. However, in this comparative example, the deposited film 110c in the MOS cell section is left unchanged with the same thickness as in the terminal section.

When the insulating film of the terminal section is thinned, it is more susceptible to the charge generated by contamination of the device surface and the like, and the breakdown voltage is more likely to decrease. Typically, in order to avoid the influence of surface charge in the terminal section, the insulating film of the terminal section is thickened nearly in proportion to the device breakdown voltage.

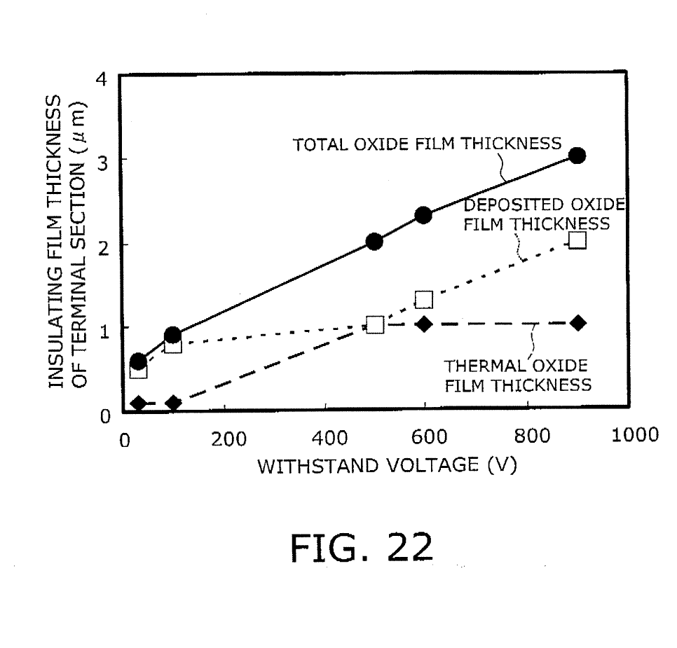

FIG. 22 is a graph showing the relationship between the insulating film thickness of the terminal section (vertical axis) and the device breakdown voltage (horizontal axis).

In devices having a high breakdown voltage of 500 V or more, the insulating film thickness of the terminal section (total oxide film thickness) needs to be 2 μm or more. The insulating film of the terminal section is composed of an oxide film formed by thermal oxidation and an oxide film deposited by chemical vapor deposition or the like. Typically, it is difficult to obtain a thermal oxide film of 1 μm or more. Thus, as the breakdown voltage of the device increases, the deposited oxide film must be thickened. Therefore, in the above comparative example where the deposited oxide film is formed in the MOS cell section with the same thickness as in the terminal section, the insulating film of the MOS cell section (including the source contact portion) is thickened particularly in devices with high breakdown voltage.

When the insulating film of the source contact portion is thickened, the aspect ratio of the source contact hole increases with the reduction of the opening width of the source contact hole opened in this insulating film, and the burying performance of the source electrode is deteriorated. Thus reduction of the source contact width, that is, downscaling of the MOS cell section, has been limited.

Conventionally, for example, the downscaling limit of the cell pitch in high voltage devices is considered to be about 12 μm. The reason for this is described below.

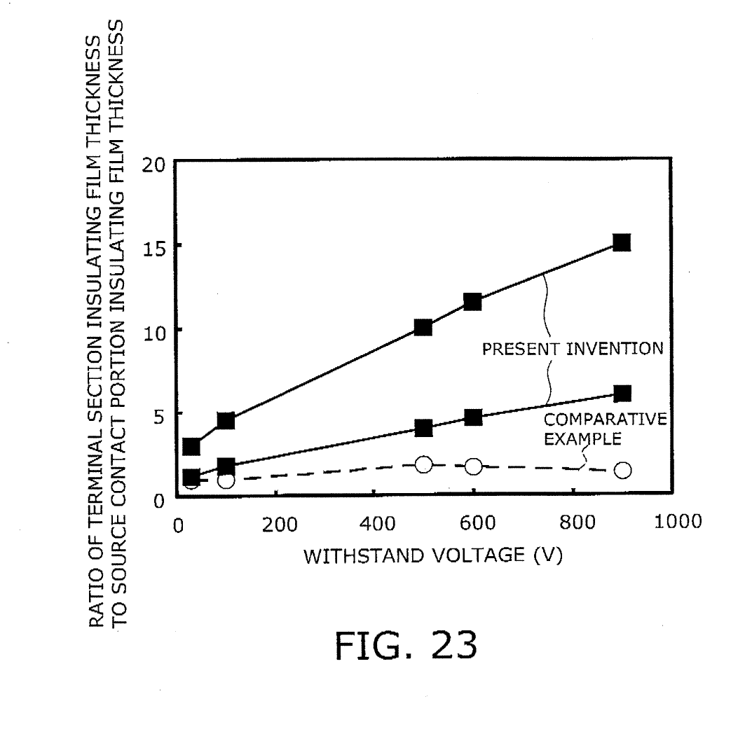

FIG. 23 is a graph showing the relationship between the breakdown voltage (horizontal axis) and the ratio of the insulating film thickness of the terminal section to the insulating film thickness of the source contact portion (vertical axis).

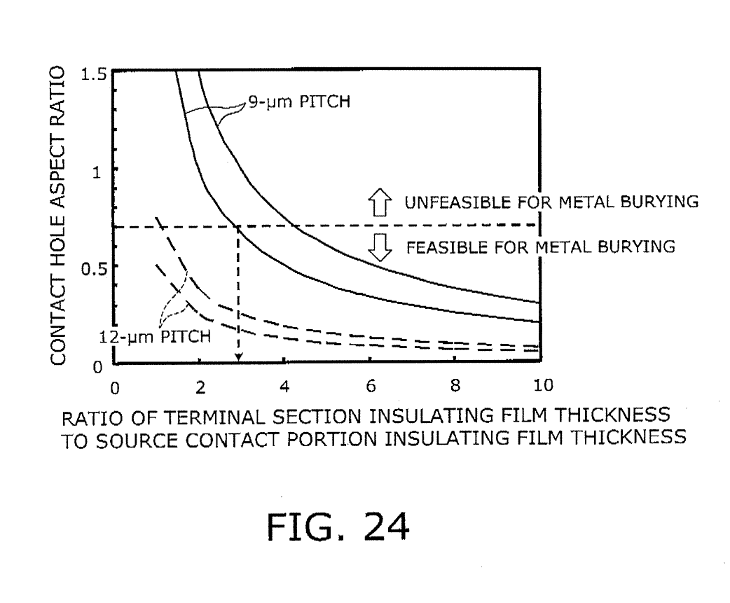

FIG. 24 is a graph showing the relationship between the ratio of the insulating film thickness of the terminal section to the insulating film thickness of the source contact portion (horizontal axis) and the aspect ratio of the source contact hole (vertical axis).

In the structure of the above comparative example, as indicated by a dashed line (hollow circles) in FIG. 23, the ratio of the insulating film thickness of the terminal section to the insulating film thickness of the source contact portion is 1 to 2. For a MOS cell pitch of 12 μm, as shown in FIG. 24, when the ratio of the insulating film thickness of the terminal section to the insulating film thickness of the source contact portion is in the range of 1.1 to 2, the aspect ratio is 0.7 or less, showing promise for good burying performance of the source electrode.

However, when the ratio of the insulating film thickness of the terminal section to the insulating film thickness of the source contact portion is 1 or less, the aspect ratio is 0.7 or more. Thus the limit of the reduction of the MOS cell pitch is 12 μm, including the process margin. A MOS cell pitch of 12 μm translates to a gate length of 6 μm, a gate-source offset length of 1 μm, and a source contact width of 4 μm.

In a vertical MOSFET without a superjunction structure having a high breakdown voltage of 500 V or more, the resistance in the drift section accounts for 80% or more, and the resistance in the MOS section accounts for 20% or less. Hence even a MOS cell pitch of about 12 to 20 μm was not problematic. However, in a high voltage MOSFET with a superjunction structure, the resistance in the drift section can be reduced to ⅕ or less. Hence the proportion accounted for by the resistance in the MOS section relatively becomes not negligible. Furthermore, unless the MOS cell is downscaled with the reduction of the cell pitch of the superjunction structure, an extra resistance will occur. Thus it becomes indispensable for a MOSFET having a superjunction structure to downscale a MOS cell.

In a MOSFET having a superjunction structure, the cell pitch is nearly proportional to the ON resistance. As compared with devices having a cell pitch of 12 μm, next-generation devices with higher characteristics require about 25% reduction of ON resistance for enhancing the characteristics. In this case, the cell pitch needs reducing to 9 μm.

However, as shown in FIG. 24, for a MOS cell pitch of 9 μm, when the ratio of the insulating film thickness of the terminal section to the insulating film thickness of the source contact portion is in the range of 1 to 2, the contact hole aspect ratio is 1 or more. To facilitate burying source metal, it is required that the insulating film thickness in the cell section be thinned to reduce the aspect ratio. As shown in FIG. 24, when the ratio of the insulating film thickness of the terminal section to the insulating film thickness of the source contact portion is increased to 3 or more, the aspect ratio is 0.7 or less even for a cell pitch of 9 μm. Thus the source contact width can be reduced to downscale the cell pitch to 9 μm while ensuring good performance of burying source metal into the source contact hole.

That is, the ratio of the insulating film thickness of the terminal section to the insulating film thickness of the source contact portion is required to be 3 or more for realizing a cell pitch as fine as 9 μm while ensuring an aspect ratio of 0.7 or less.

More specifically, the MOS cell section needs only to have a breakdown voltage of about 30 V, for example, for the gate-source voltage. However, the terminal section subjected to the drain voltage requires higher breakdown voltage. The insulating film thickness of the terminal section is determined so as to ensure this high breakdown voltage. Thus, by selecting the insulating film thickness of the MOS cell section (source contact portion) to be ⅓ or less of the insulating film thickness of the terminal section, the MOS cell can be downscaled to reduce the ON resistance with maintaining high breakdown voltage and without increasing the aspect ratio of the source contact hole.

In the semiconductor device according to this embodiment shown in FIG. 20, the thickness of the insulating film in the portion which is formed on the source contact portion and through which a source contact hole is opened is the sum of the thickness of the gate insulating film 107a and the thickness of the silicon nitride film 110b. Furthermore, a thermal oxide film 107b of polysilicon serving as a gate electrode material and a silicon nitride film 110b are formed on the gate electrode 108. The thermal oxide film 107b has nearly the same thickness as the gate insulating film 107a, which is also a thermal oxide film. Thus the thickness of the insulating film formed on the gate electrode 108 (corresponding to a in FIG. 10) is comparable to that of the insulating film on the source contact portion.

Therefore the above-described condition that the insulating film thickness of the source contact portion is ⅓ or less of the insulating film thickness of the terminal section (corresponding to b in FIG. 10) translates to a condition that the insulating film thickness a on the gate electrode 108 is ⅓ or less of the insulating film thickness b of the terminal section.

Furthermore, in FIG. 23, the solid line (plotted as solid squares) represents the relationship between the breakdown voltage and the ratio of the insulating film thickness of the terminal section to the insulating film thickness of the source contact portion for the semiconductor device according to the embodiment of the invention it can be seen from FIG. 23 that, in the range of breakdown voltage of 500 to 900 V, the ratio of the insulating film thickness of the terminal section to the insulating film thickness of the source contact portion has a maximum of 15. Therefore, if the insulating film thickness of the source contact portion (=the insulating film thickness a on the gate electrode 108) is 1/15 or more of the insulating film thickness b of the terminal section, there is no problem with devices having a high breakdown voltage of 500 to 900 V.

Although not depicted in FIGS. 10 and 20, a field stop layer is preferably formed on the surface of the terminal section so that the depletion layer does not reach the dicing line.

FIGS. 10 and 20 show a field plate structure where the source electrode overhangs the terminal section. However, the terminal structure is not limited thereto. For example, RESURF (Reduced Surface Field) structure, field plate structure or guard ring structure may be appropriately employed as the terminal structure.

The process flow is not limited to that described above with reference to FIGS. 12 to 20.

### Seventh Embodiment

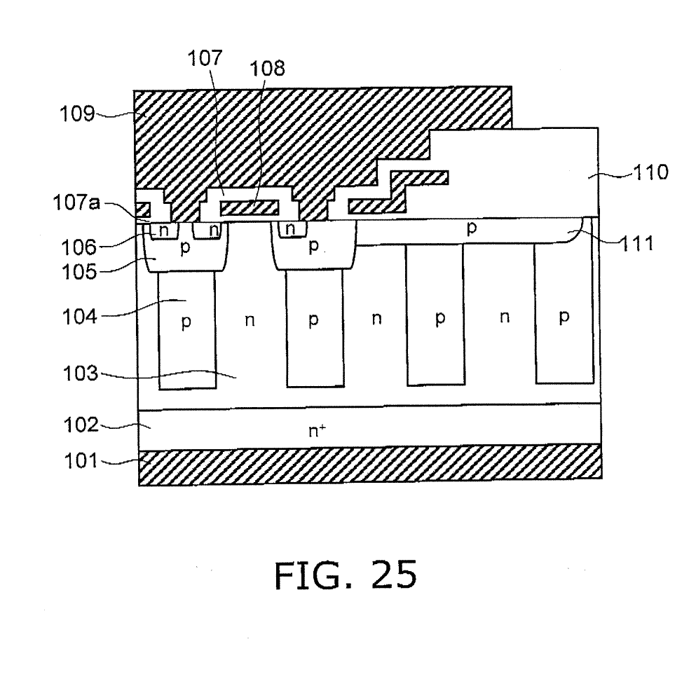

FIG. 25 is a schematic view illustrating the cross-sectional structure of the main part of a semiconductor device according to a seventh embodiment of the invention.

In this embodiment, a p-type RESURF (Reduced Surface Field) layer 111 connected to the source electrode 109 is provided on the surface of the terminal section to alleviate electric field concentration in the terminal section. In order to obtain a high breakdown voltage, RESURF layer 111 is formed shallower than the base region 105.

### Eighth Embodiment

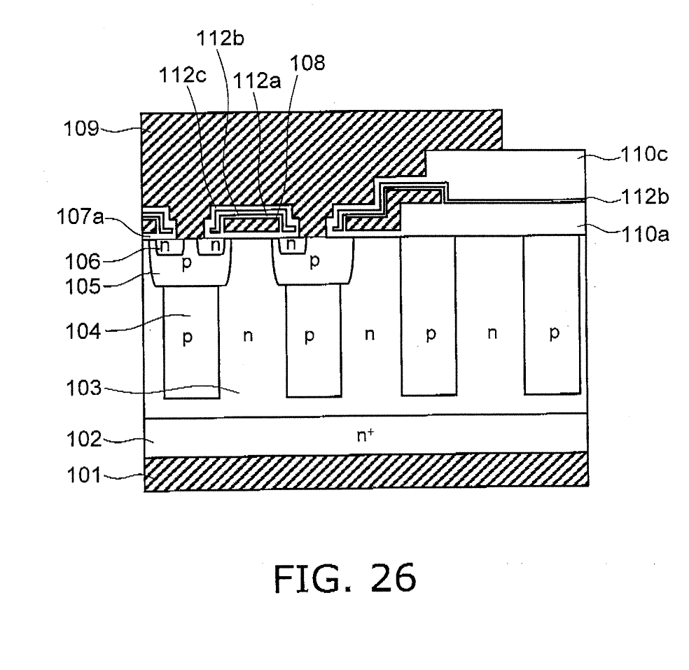

FIG. 26 is a schematic view illustrating the cross-sectional structure of the main part of a semiconductor device according to an eighth embodiment of the invention.

The semiconductor device according to this embodiment is obtained by the following process.

After the process described above with reference to FIG. 16, the gate electrode (polysilicon) 108 is thermally oxidized to form a thermal oxide film 112a covering the gate electrode 108. Then a silicon nitride film (deposited film) 112b covering the thermal oxide film 112a is formed. Then a silicon oxide film 110c is formed on the silicon nitride film 112b.

Next, the silicon oxide film 110c in the device section is selectively etched away. Then the silicon nitride film 112b on the gate electrode 108 is thermally oxidized to form a silicon oxide film 112c covering the silicon nitride film 112b. Then a source contact hole is opened in the source contact portion to form a source electrode 109.

### Ninth Embodiment

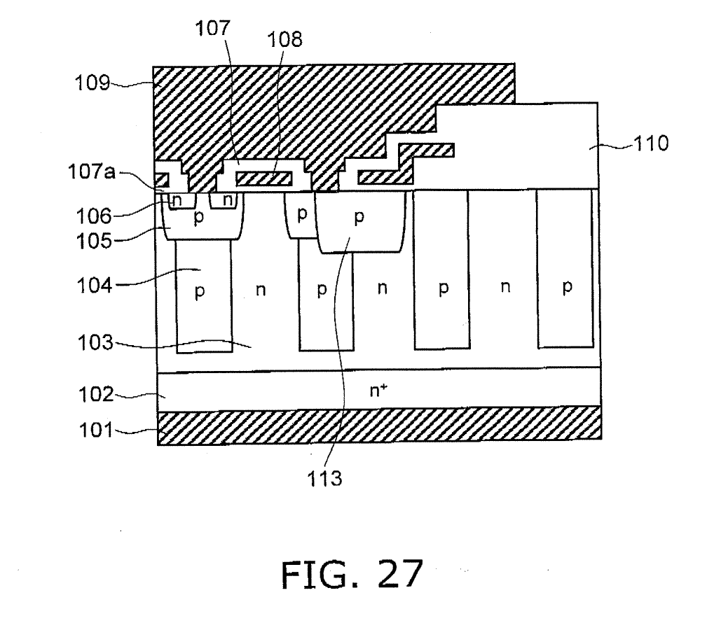

FIG. 27 is a schematic view illustrating the cross-sectional structure of the main part of a semiconductor device according to a ninth embodiment of the invention.

The semiconductor device according to this embodiment has a p-type guard ring layer 113, which is deeper than the base region 105, around the outer periphery of the device section.

If the gate length is reduced to downsize the MOS cell, the spacing between the base regions 105 is narrowed, and hence the resistance in the n-type pillar region 103 between the base regions 105 increases. Therefore, to reduce the cell pitch while preventing the resistance increase in the MOS gate portion, the base region 105 must be shallowed. However, if the base region 105 is shallowed, then the curvature at the corner of the base region 105 increases, and the electric field concentrates particularly on the terminal section, thereby decreasing the breakdown voltage.

Thus, in this embodiment, a p-type guard ring layer 113 deeper than the base region 105 is provided in the terminal section. The depth of the guard ring layer 113 is made comparable to or deeper than that of the conventional base region to maintain the breakdown voltage, whereas the base region 105 is shallowed to allow the cell pitch to be reduced.

Conventionally, the cell pitch of a MOS gate is 12 to 16 μm, which is the same as the cell pitch of the superjunction structure. The gate length is 6 μm, the channel length is 2 μm, and the base region depth is about 3 to 4 μm.

In contrast, if the depth of the above-described guard ring layer 113 is 3 to 4 μm and the depth of the base region 105 is 1.5 μm, then the gate length can be reduced to 3 μm, and the cell pitch of the MOS gate structure can be reduced to 6 μm. Thus the cell pitch of the superjunction structure can likewise be reduced to 6 μm.

The doping concentration in the guard ring layer 113 can be freely determined because the guard ring layer 113 does not affect the gate threshold voltage. The doping concentration in the guard ring layer 113 is preferably higher than in the base region 105 for forming a deep diffusion layer and decreasing the hole extraction resistance.

While the guard ring layer 113 is formed below the outermost gate electrode 108 in FIG. 27, the guard ring layer 113 may be formed further outside.

### Tenth Embodiment

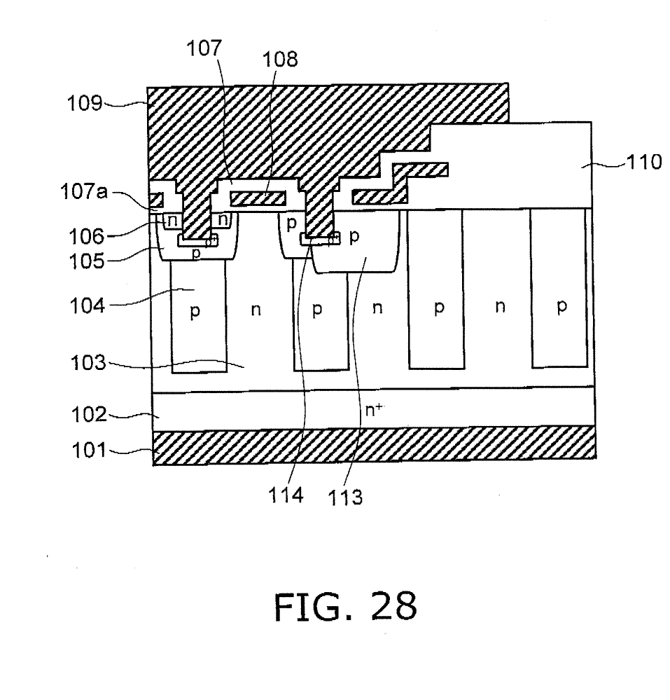

FIG. 28 is a schematic view illustrating the cross-sectional structure of the main part of a semiconductor device according to a tenth embodiment of the invention.

If the base region 105 is shallowed, the parasite bipolar transistor composed of the source region 106, the base region 105, and the n-type pillar region 103 has a large gain. This causes a concern about the decrease of avalanche withstand capability whereby the parasite bipolar transistor is operated at the time of avalanche breakdown and leads to device breakdown.

Thus, in this embodiment, as shown in FIG. 28, a trench is formed in the base region 105, and a p⁺-type contact layer 114 is provided at the bottom of the trench. The source electrode 109 forms a junction with the p⁺-type contact layer 114. This is the so-called trench contact structure of the source electrode. Thus the hole extraction resistance in the base region 105 can be reduced to avoid the operation of the parasite bipolar transistor. Hence the decrease of avalanche withstand capability can be prevented.

In FIG. 28, a trench is formed in the base region 105, and a p⁺-type contact layer 114 is provided at the bottom of the trench. However, rather than forming a trench, a p⁺-type contact layer 114 may be selectively provided in the surface portion of the base region 105.

### Eleventh Embodiment

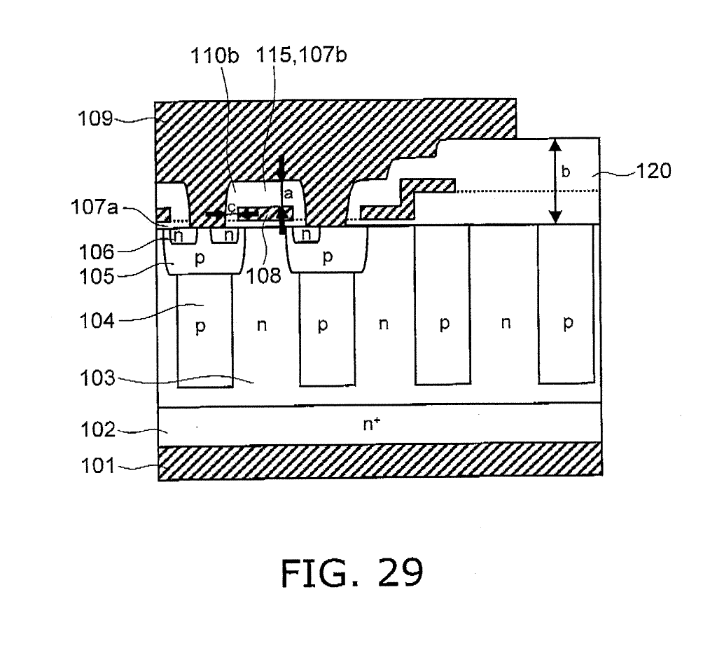

FIG. 29 is a schematic view illustrating the cross-sectional structure of the main part of a semiconductor device according to an eleventh embodiment of the invention.

In this embodiment, the contact opening through which the source electrode 109 is in contact with the base region 105 and the source region 106 is formed in a self-aligned manner.

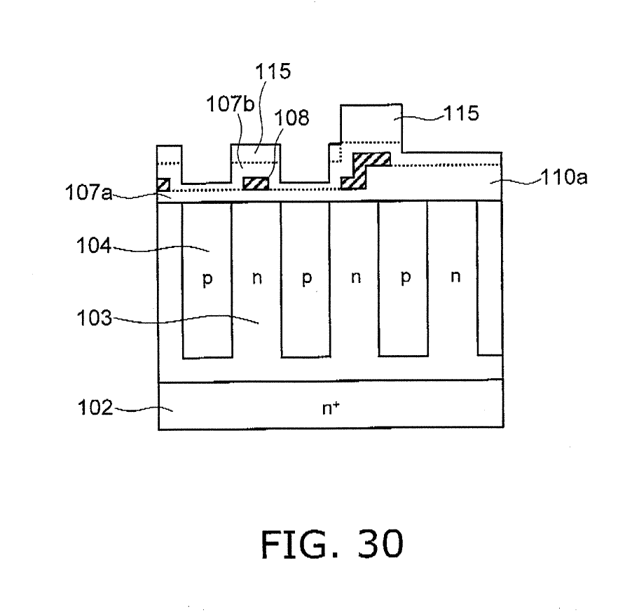

FIGS. 30 to 34 are process cross-sectional views illustrating the main part of a process of manufacturing a semiconductor device according to this embodiment.

The process up to depositing a gate electrode (polysilicon) 108 is the same as the flow up to FIG. 15 in the sixth embodiment described above. After the gate electrode (polysilicon) 108 is deposited, the surface is thermally oxidized to form an oxide film 107b. Then, as shown in FIG. 30, an insulating film 115 is formed. Then the insulating films 115, 107b and the polysilicon 108 are patterned, and thermally oxidized again to form an oxide film on the sidewall of the gate electrode (polysilicon) 108. The insulating film 115 is a silicon oxide film or silicon nitride film deposited by chemical vapor deposition, for example.

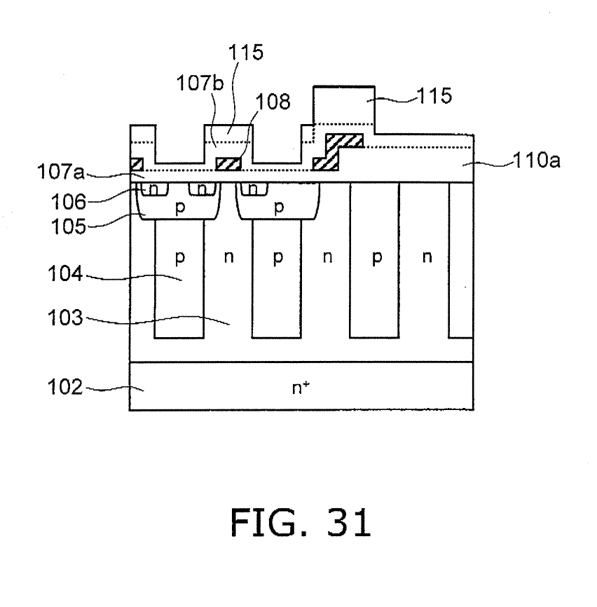

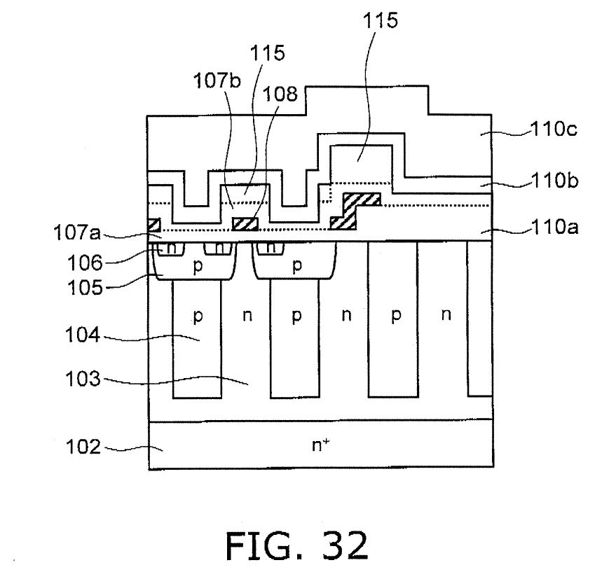

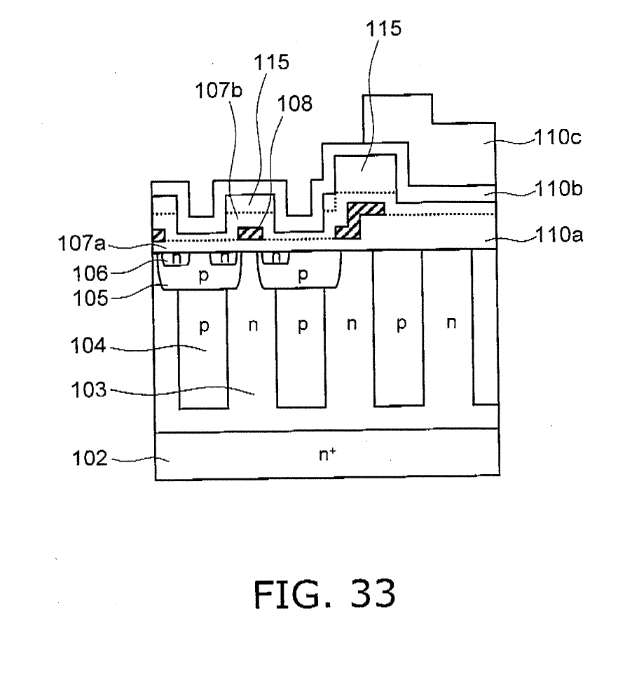

Subsequently, as shown in FIG. 31, a base region 105 and a source region 106 are formed by ion implantation and diffusion. Then, as shown in FIG. 32, a silicon nitride film 110b is deposited on the insulating film 115, and a silicon oxide film 110c is deposited further thereon. Then, as shown in FIG. 33, the silicon oxide film 110c of the device section is etched away.

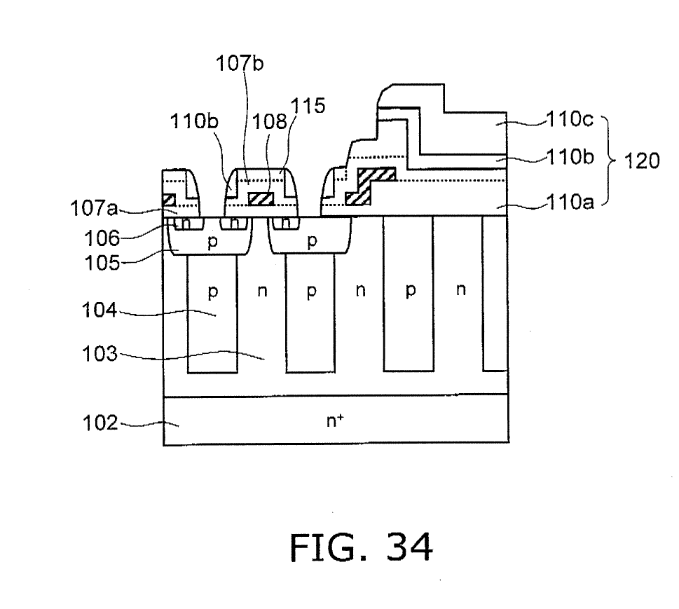

Then, as shown in FIG. 34, the entire surface is etched back by the RIE (Reactive Ion Etching) technique, for example, to open a source contact hole. In this dry etching, the etching rate is low in the lateral direction and high in the vertical direction. Thus the contact hole can be formed with the insulating film being left on the sidewall of the gate electrode 108. By previously depositing a thick insulating film 115 on the gate electrode 108, it is possible to leave an insulating film having a sufficient thickness on the gate electrode 108 even if the insulating film on the gate electrode 108 is thinned by etching back. Thus the gate-source breakdown voltage can be retained.

In the semiconductor device thus obtained according to this embodiment, the thickness a (see FIG. 29) of the insulating films (the thermal oxide film 107b and the insulating film 115) on the gate electrode 108 is larger than the lateral dimension c of the insulating film beside the gate electrode 108.

In this embodiment again, as in the above embodiments, the insulating film thickness a on the gate electrode 108 is ⅓ or less of the thickness b of the insulating film 120 on the surface of the terminal section. Thus the increase of aspect ratio of the source contact hole can be prevented.

Furthermore, the gate-source offset distance is typically determined to be 1 μm or more by the alignment accuracy of lithography. However, in this embodiment, the source contact hole can be formed in a self-aligned manner by etching back the entire surface using anisotropic etching. Thus no misalignment occurs, and the offset distance can be minimized to the distance required for retaining the gate-source breakdown voltage.

The thickness of the insulating film remaining beside the gate electrode 108 becomes the gate-source offset distance, which can be controlled by the thickness of the thermal oxide film 107b of the gate electrode (polysilicon) 108 and the thickness of the silicon nitride film 110b. For example, when the thermal oxide film 107b has a thickness of 0.1 to 0.2 μm and the silicon nitride film 110b has a thickness of 0.1 to 0.2 μm, the gate-source offset distance can be reduced to 0.2 to 0.4 μm.

The source length is determined by the sum of the contact width of the source electrode 109 and the gate-source offset distance. As described above in the foregoing embodiments, the contact width can be reduced by thinning the insulating film thickness of the device section. This embodiment further allows the gate-source offset distance to be reduced. As a result, the source length can be further reduced.

### Twelfth Embodiment

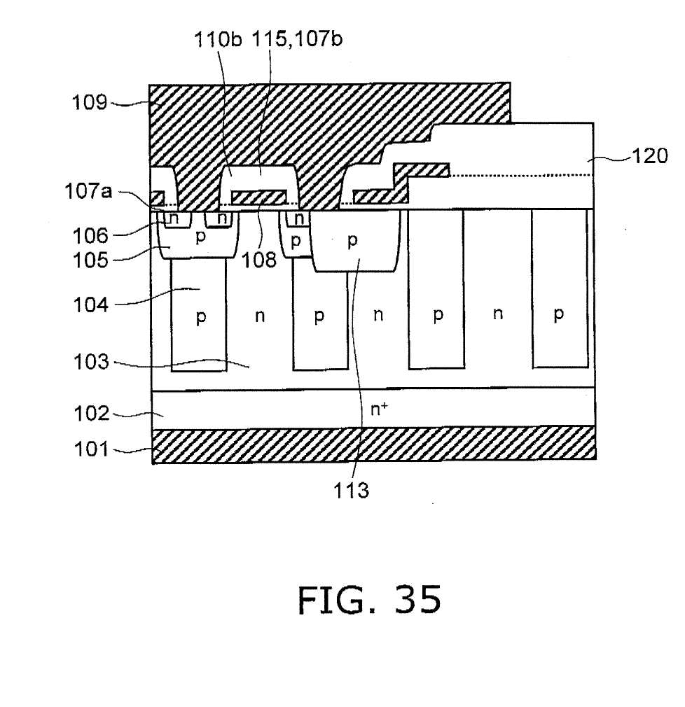

FIG. 35 is a schematic view illustrating the cross-sectional structure of the main part of a semiconductor device according to a twelfth embodiment of the invention.

In this embodiment, the outer periphery of the device section is further surrounded by a guard ring layer 113, which allows the base region 105 to be shallowed and the gate length to be reduced. Thus the MOS gate pitch can be further downscaled.

### Thirteenth Embodiment

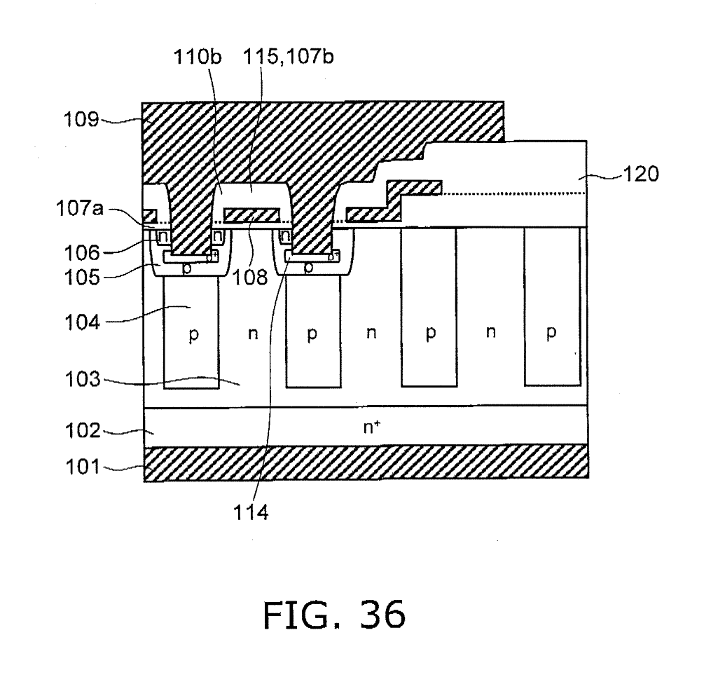

FIG. 36 is a schematic view illustrating the cross-sectional structure of the main part of a semiconductor device according to a thirteenth embodiment of the invention.

In addition to the structure of the semiconductor device according to the eleventh embodiment described above, this embodiment adopts a trench contact structure of the source electrode 109 as in the fifth embodiment. Thus the hole ejection at the time of avalanche breakdown is accelerated, and the avalanche withstand capability can be enhanced.

### Fourteenth Embodiment

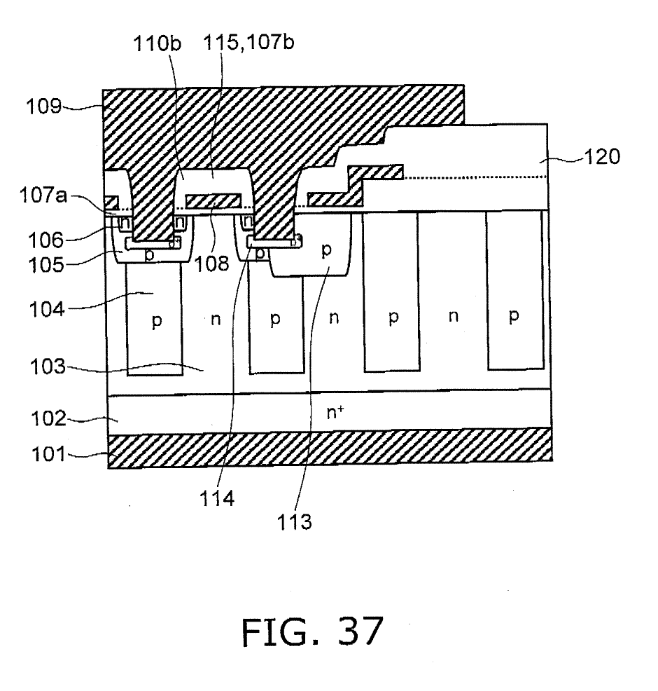

FIG. 37 is a schematic view illustrating the cross-sectional structure of the main part of a semiconductor device according to a fourteenth embodiment of the invention.

In this embodiment, a guard ring layer 113 is provided in addition to the structure of the semiconductor device according to the thirteenth embodiment described above.

### Fifteenth Embodiment

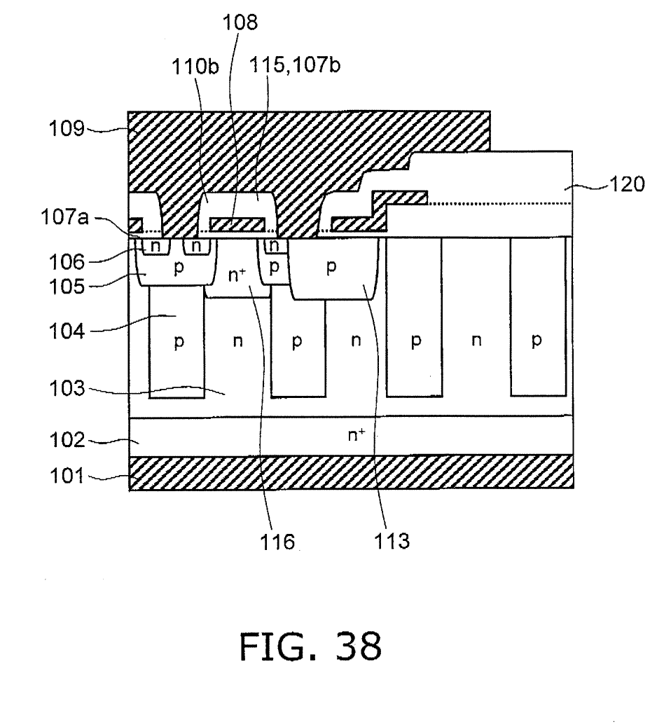

FIG. 38 is a schematic view illustrating the cross-sectional structure of the main part of a semiconductor device according to a fifteenth embodiment of the invention.

In this embodiment, a highly doped n⁺-silicon region 116 is provided between the base regions 105. Thus the resistance between the base regions 105 can be reduced, and hence the ON resistance can be reduced.

In FIG. 38, the highly doped n⁺-silicon region 116 is formed deeper than the base region 105. However, the highly doped n⁺-silicon region 116 may be shallower than the base region 105. Furthermore, FIG. 38 shows a structure where a highly doped n⁺-silicon region 116 is added to the structure of the twelfth embodiment shown In FIG. 35. However, the highly doped n⁺-silicon region 116 can also be formed in the structure of any of the embodiments other than the twelfth embodiment to reduce the ON resistance.

Embodiments of the invention have been described with reference to specific examples. However, the invention is not limited thereto, but the embodiments can be variously modified within the spirit of the invention.

While the description of the foregoing examples assumes the first conductivity type as n-type and the second conductivity type as p-type, the invention can also be practiced assuming the first conductivity type as p-type and the second conductivity type as n-type.

The planar pattern of the MOS gate portion and the superjunction structure is not limited to the striped configuration, but may be in a lattice or staggered configuration.

The superjunction structure is not limited to the methods described above, but can be formed by various methods such as a method of conducting a plurality of iterations of ion implantation and epitaxial growth, a method of forming a trench followed by buried growth, or a method of forming a trench followed by ion implantation into the trench sidewall.

In the above description, the semiconductor used in the MOSFETs is silicon (Si). However, compound semiconductors such as silicon carbide (SiC) and gallium nitride (GaN) or wide bandgap semiconductors such as diamond can be used as the semiconductor.

The invention is not limited to application to MOSFET devices, but is also applicable to hybrid devices of MOSFETs and SBDs (Schottky Barrier Diodes), or IGBTs (Insulated Gate Bipolar Transistors), as long as they have a superjunction structure.

1. A semiconductor device comprising:
a semiconductor layer of a first conductivity type;
a plurality of first semiconductor pillar regions of the first conductivity type provided on a major surface of the semiconductor layer;
a plurality of second semiconductor pillar regions of a second conductivity type provided on the major surface of the semiconductor layer and being adjacent to the first semiconductor pillar regions;
a first main electrode provided on a side opposite to the major surface of the semiconductor layer;
a first semiconductor region of the second conductivity type provided on the first and second semiconductor pillar regions;
a second semiconductor region of the first conductivity type provided in a surface portion of the first semiconductor region;
a second main electrode provided on the second semiconductor region;
a trench being adjacent to the first semiconductor region and the second semiconductor region and reaching the first semiconductor pillar region from the surface side of the second semiconductor region;
an insulating film provided on an inner wall surface of the trench; and
a control electrode buried inside the trench via the insulating film,
doping concentration in the vertical direction at the center of the width of the second semiconductor pillar region being substantially constant up to a substantially intermediate portion in the direction from the second main electrode toward the first main electrode and gradually decreasing from the substantially intermediate portion toward the first main electrode.

2. The semiconductor device according to claim 1, wherein the doping concentration in the first semiconductor pillar region between the trench and the second semiconductor pillar region is higher than in the other portion.

3. The semiconductor device according to claim 1, wherein, at the substantially intermediate portion in the direction from the second main electrode toward the first main electrode, the doping concentration in the first semiconductor pillar region is minimized and lower than the doping concentration in the second semiconductor pillar region.

4. The semiconductor device according to claim 1, wherein the width of the second semiconductor pillar region is narrowed stepwise from the second main electrode toward the first main electrode.

5. The semiconductor device according to claim 1, wherein a doping concentration in a first semiconductor region of the second conductivity type is higher than in the second semiconductor pillar region.

6. The semiconductor device according to claim 1, wherein the doping concentration in the first semiconductor pillar region is higher than in the second semiconductor pillar region at a position closer to the semiconductor layer of the first conductivity type.

7. A semiconductor device comprising:
a semiconductor layer of a first conductivity type;
a first semiconductor pillar region of the first conductivity type provided on a major surface of the semiconductor layer;
a second semiconductor pillar region of a second conductivity type provided on the major surface of the semiconductor layer and being adjacent to the first semiconductor pillar region;
a first main electrode provided on an opposite side of the major surface of the semiconductor layer;
a first semiconductor region of the second conductivity type provided on the second semiconductor pillar region;
a second semiconductor region of the first conductivity type selectively provided in a surface of the first semiconductor region;
a second main electrode provided on the first semiconductor region and the second semiconductor region;
a first insulating film provided on the first semiconductor pillar region, the first semiconductor region, and the second semiconductor region;
a control electrode provided on the first insulating film;
a second insulating film provided on the control electrode; and
a third insulating film provided on the major surface side of the semiconductor layer in a terminal section adjacent to a device section where the control electrode is located,
a thickness of the second insulating film is ⅓ or less of a thickness of the third insulating film.

8. The semiconductor device according to claim 7, wherein the thickness of the second insulating film is 1/15 or more of the thickness of the third insulating film.

9. The semiconductor device according to claim 7, wherein the second insulating film includes a thermal oxide film formed by thermal oxidation of the control electrode and a deposited film deposited on the thermal oxide film.

10. The semiconductor device according to claim 9, wherein the thermal oxide film is a silicon oxide film and the deposited film is a silicon nitride film.

11. The semiconductor device according to claim 9, wherein the thermal oxide film and the deposited film are silicon oxide films.

12. The semiconductor device according to claim 7, further comprising a third semiconductor region of the second conductivity type provided under the third insulating film, the second semiconductor region of the second conductivity type being connected to the second main electrode.

13. The semiconductor device according to claim 12, wherein the third semiconductor region of the second conductivity type is formed shallower than the first semiconductor region of the second conductivity type.

14. The semiconductor device according to claim 7, further comprising a fourth semiconductor region of the second conductivity type provided at a surface of the semiconductor layer, the fourth semiconductor region of the second conductivity type being formed deeper than the first semiconductor region of the second conductivity type.

15. The semiconductor device according to claim 14, wherein the doping concentration in the fourth semiconductor region of the second conductivity type is higher than in the first semiconductor region of the second conductivity type.

16. The semiconductor device according to claim 7, wherein a trench is formed in the first semiconductor region of the second conductivity type, and the trench is filled with a part of the second main electrode.

17. The semiconductor device according to claim 7, further comprising a fourth insulating film provided on a side face of the control electrode,
wherein the thickness of the second insulating film is greater than a thickness of the fourth insulating film.

18. A method of manufacturing a semiconductor device comprising:
etching a first semiconductor layer of a first conductivity type from a major surface side thereof in a plurality of steps to form a trench having a width that is narrowed stepwise along the depth from the major surface side;
burying a second semiconductor layer of a second conductivity type in the trench;
forming a first semiconductor region of the second conductivity type in a surface portion of the second semiconductor layer;
forming a second semiconductor region of the first conductivity type in a surface portion of the first semiconductor region;
forming a first main electrode on an opposite side of the major surface of the first semiconductor layer; and
forming a second main electrode in contact with the second semiconductor region.

19. The method of manufacturing the semiconductor device according to claim 18, wherein the etching the first semiconductor layer includes:
forming a first trench by etching the first semiconductor layer of the first conductivity type from the major surface side thereof;
forming an insulating film on an inner wall of the first trench;
forming a second trench by etching a bottom surface of the first trench while leaving the insulating film formed on a inner side wall of the first trench;
removing the insulating film on the inner wall of the first trench.

20. The method of manufacturing the semiconductor device according to claim 19, wherein the etching is performed by a reactive ion etching.
